(19) United States
(12) Patent Application Publication
(10) Pub. No.: US 2023/0335398 A1
(43) Pub. Date: Oct. 19, 2023

(54) SUBSTRATE PROCESSING METHOD, METHOD OF MANUFACTURING SEMICONDUCTOR DEVICE, SUBSTRATE PROCESSING APPARATUS AND NON-TRANSITORY COMPUTER-READABLE RECORDING MEDIUM

(71) Applicant: Kokusai Electric Corporation, Tokyo (JP)

(72) Inventors: Yuki TAIRA, Toyama (JP); Tsuyoshi TAKEDA, Toyama (JP); Masaru KADOSHIMA, Toyama (JP)

(21) Appl. No.: 18/336,634

(22) Filed: Jun. 16, 2023

Related U.S. Application Data
(63) Continuation of application No. PCT/JP2021/047165, filed on Dec. 21, 2021.

(30) Foreign Application Priority Data
Dec. 24, 2020 (JP) 2020-214783

(51) Int. Cl. H01L 21/02; H01J 37/32; C23C 16/34; C23C 16/44; C23C 16/52; C23C 16/455

(52) U.S. Cl. CPC H01L 21/0228; H01J 37/32449; C23C 16/345; C23C 16/4412; C23C 16/52; C23C 16/45557; H01J 37/32568; H01J 37/32825; C23C 16/4408; H01J 2237/3321

(57) ABSTRACT

According to one aspect of the technique of the present disclosure, there is provided a substrate processing method including: forming a film on a substrate by performing a cycle a predetermined number of times, wherein the cycle includes: (a) supplying a source gas to the substrate; (b) supplying a plasma-excited gas containing nitrogen and hydrogen to the substrate by exciting a gas containing nitrogen and hydrogen into a plasma state; and (c) supplying a plasma-excited inert gas to the substrate by exciting an inert gas into a plasma state, wherein a pressure of a space where the substrate is present is set to be lower in (c) than in (b).

### CROSS REFERENCE TO RELATED APPLICATIONS

This application is a bypass continuation application of PCT International Application No. PCT/JP2021/047165, filed on Dec. 21, 2021, in the WIPO, the international application being based upon and claiming the benefit of priority from Japanese Patent Application No. 2020-214783, filed on Dec. 24, 2020, in the Japanese Patent Office, the entire contents of which are hereby incorporated by reference.

### TECHNICAL FIELD

The present disclosure relates to a substrate processing method, a method of manufacturing semiconductor device, a substrate processing apparatus and a non-transitory computer-readable recording medium.

### BACKGROUND

A semiconductor device such as a memory device (such as a flash memory and a DRAM) and a logic device (such as a CPU) is becoming highly integrated year by year. For a high integration of the semiconductor device, a method (technique) capable of forming an ultra-thin film on a fine circuit pattern with a high precision is preferably used, and as a film-forming method therefor, for example, a method of alternately supplying a source gas and a reactive gas to a substrate may be used. In recent years, since parameters such as wiring dimensions are miniaturized, it becomes important to improve a uniformity or a quality of a film formed on the substrate and a reproducibility thereof. Further, along with changes in a structure or a material of a next-generation semiconductor device, it is preferable to use a film-forming technique capable of obtaining (forming) a high quality film at a low temperature.

For example, a silicon nitride film (also simply referred to as a “SiN film”) may be formed as the film formed on the substrate. For example, the SiN film may be used as an etching stopper layer when etching a silicon oxide film (also simply referred to as a “SiO film”) or the like using hydrogen fluoride (also simply referred to as a “HF”) aqueous solution. According to some related arts, as the film-forming technique capable of forming the SiN film, a technique capable of forming the film at a low temperature using a plasma may be used.

However, when the film is formed at the low temperature using the plasma, a wet etching resistance of the film may be lowered. Thereby, the quality of the film may deteriorate.

### SUMMARY

According to the present disclosure, there is provided a technique capable of forming a high quality film at a low temperature using a plasma.

According to one aspect of the technique of the present disclosure, there is provided a substrate processing method including: forming a film on a substrate by performing a cycle a predetermined number of times, wherein the cycle includes: (a) supplying a source gas to the substrate; (b) supplying a plasma-excited gas containing nitrogen and hydrogen to the substrate by exciting a gas containing nitrogen and hydrogen into a plasma state; and (c) supplying a plasma-excited inert gas to the substrate by exciting an inert gas into a plasma state, wherein a pressure of a space where the substrate is present is set to be lower in (c) than in (b).

### BRIEF DESCRIPTION OF THE DRAWINGS

FIG. 1 is a diagram schematically illustrating a vertical cross-section of a vertical type process furnace 202 of a substrate processing apparatus preferably used in one or more embodiments of the present disclosure.

FIG. 2 is a diagram schematically illustrating a horizontal cross-section, taken along a line A-A shown in FIG. 1, of the vertical type process furnace 202 of the substrate processing apparatus preferably used in the embodiments of the present disclosure.

FIG. 3 is a block diagram schematically illustrating a configuration of a controller 121 and related components of the substrate processing apparatus preferably used in the embodiments of the present disclosure.

FIG. 4 is a diagram schematically illustrating a perspective view of an electrode structure of the substrate processing apparatus preferably used in the embodiments of the present disclosure.

FIG. 5 is a diagram schematically illustrating an exemplary process sequence according to the embodiments of the present disclosure.

FIG. 6 is a diagram schematically illustrating an exemplary process sequence according to a first modified example of the embodiments of the present disclosure.

FIG. 7A is a diagram schematically illustrating an example in which an interval between adjacent wafers among a plurality of wafers 200 is set to a reference interval that enables the boat 217 to accommodate the maximum number of wafers supportable by the boat 217.

FIG. 7B is a diagram schematically illustrating another example in which the interval between adjacent wafers among the plurality of wafers 200 is set to be twice or more the reference interval.

FIG. 7C is a diagram schematically illustrating still another example in which the interval between adjacent wafers among the plurality of wafers 200 is set to be four times or more the reference interval.

FIG. 8 is a diagram schematically illustrating measurement results of a wet etching rate (WER) on a surface of a silicon nitride film (SiN film) formed on an evaluation sample #1 and a thickness of the SiN film formed on the evaluation sample #1.

FIG. 9 is a diagram schematically illustrating measurement results of a wet etching rate (WER) on a surface of a silicon nitride film (SiN film) formed on an evaluation sample #2 and a thickness of the SiN film formed on the evaluation sample #2.

FIG. 10 is a diagram schematically illustrating measurement results of a wet etching rate (WER) on a surface of a silicon nitride film (SiN film) formed on an evaluation sample #3 and a thickness of the SiN film formed on the evaluation sample #3.

FIG. 11 is a diagram schematically illustrating measurement results of a wet etching rate (WER) on a surface of a silicon nitride film (SiN film) formed on an evaluation sample #4 and a thickness of the SiN film formed on the evaluation sample #4.

### DETAILED DESCRIPTION

### Embodiments of Present Disclosure

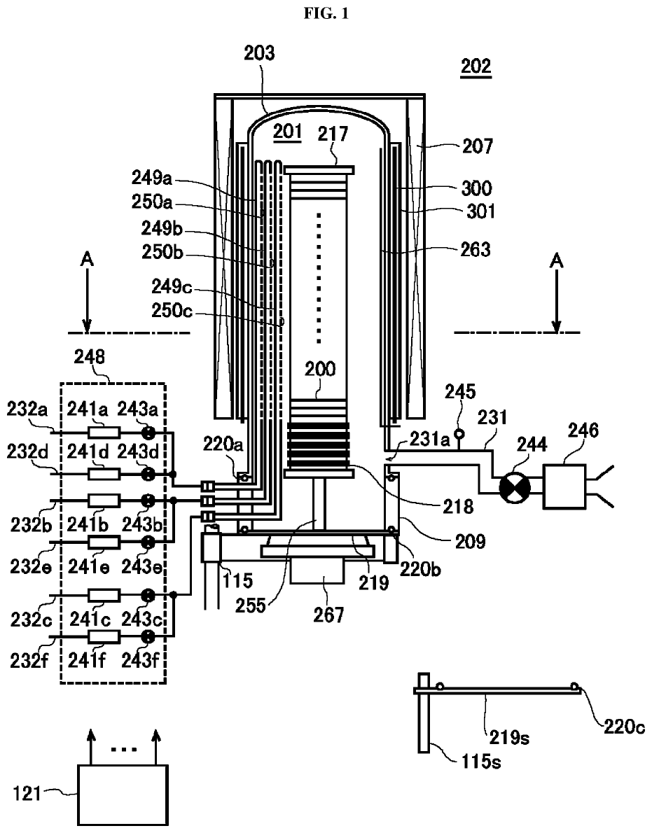

Hereinafter, one or more embodiments (also simply referred to as “embodiments”) of the technique of the present disclosure will be described in detail mainly with reference to FIGS. 1 through 5 and FIGS. 7A through 7C. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) CONFIGURATION OF SUBSTRATE PROCESSING APPARATUS

As shown in FIG. 1, a substrate processing apparatus according to the present embodiments includes a vertical type process furnace (also simply referred to as a “process furnace”) 202. The process furnace 202 includes a heater 207 serving as a temperature regulator (which is a heating structure). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO2) and silicon carbide (SiC). For example, the reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers including a wafer 200 serving as a substrate. Hereinafter, the plurality of wafers including the wafer 200 may also be simply referred to as “wafers 200”. The wafer 200 is processed in the process chamber 201, that is, in the process vessel.

Nozzles 249a, 249b and 249c are provided in the process chamber 201 so as to penetrate a side wall of the manifold 209. The nozzle 249a serves as a first supplier (which is a first supply structure), the nozzle 249b serves as a second supplier (which is a second supply structure) and the nozzle 249c serves as a third supplier (which is a third supply structure). The nozzles 249a, 249b and 249c may also be referred to as a first nozzle 249a, a second nozzle 249b and a third nozzle 249c, respectively. For example, each of the nozzles 249a, 249b and 249c is made of a heat resistant material such as quartz and silicon carbide (SiC). Gas supply pipes 232a, 232b and 232c are connected to the nozzles 249a, 249b and 249c, respectively. The nozzles 249a through 249c are different nozzles. The nozzles 249a and 249c are provided adjacent to the nozzle 249b such that the nozzle 249b is located between the nozzles 249a and 249c.

Mass flow controllers (also simply referred to as “MFCs”) 241a, 241b and 241c serving as flow rate controllers (flow rate control structures) and valves 243a, 243b and 243c serving as opening/closing valves are sequentially installed at the gas supply pipes 232a, 232b and 232c, respectively, in this order from upstream sides to downstream sides of the gas supply pipes 232a, 232b and 232c in a gas flow direction. Gas supply pipes 232d, 232e and 232f are connected to the gas supply pipes 232a, 232b and 232c, respectively, at downstream sides of the valve 243a, 243b and 243c of the gas supply pipes 232a, 232b and 232c. MFCs 241d, 241e and 241f and valves 243d, 243e and 243f are sequentially installed at the gas supply pipes 232d, 232e and 232f, respectively, in this order from upstream sides to downstream sides of the gas supply pipes 232d, 232e and 232f in the gas flow direction. For example, each of the gas supply pipes 232a through 232f is made of a metal material such as SUS.

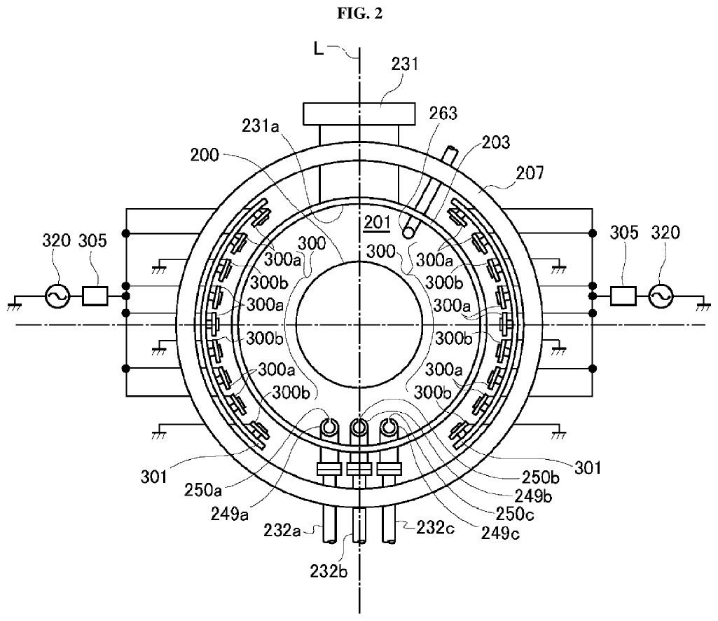

As shown in FIGS. 1 and 2, each of the nozzles 249a through 249c is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along an arrangement direction of the wafers 200). That is, each of the nozzles 249a through 249c is installed in a region that is located beside and horizontally surrounds a wafer arrangement region in which the wafers 200 are arranged (stacked) along the wafer arrangement region. When viewed from above, the nozzle 249b is arranged so as to face an exhaust port 231a described later along a straight line (denoted by “L” shown in FIG. 2) with a center of the wafer 200 transferred (loaded) into the process chamber 201 interposed therebetween. The nozzles 249a and 249c are arranged along the inner wall of the reaction tube 203 (that is, along an outer periphery of the wafer 200) such that the straight line L passing through the nozzle 249b and a center of the exhaust port 231a is interposed therebetween. The straight line L may also be referred to as a straight line passing through the nozzle 249b and the center of the wafer 200. That is, it can be said that the nozzle 249c is provided opposite to the nozzle 249a with the straight line L interposed therebetween. The nozzles 249a and 249c are arranged line-symmetrically (that is, in a line symmetry) with respect to the straight line L serving as an axis of symmetry. A plurality of gas supply holes 250a, a plurality of gas supply holes 250b and a plurality of gas supply holes 250c are provided at side surfaces of the nozzles 249a, 249b and 249c, respectively. Gases are supplied via the gas supply holes 250a through the gas supply holes 250c, respectively. The gas supply holes 250a through the gas supply holes 250c are open toward the exhaust port 231a when viewed from above, and are configured such that the gases are supplied toward the wafers 200 via the gas supply holes 250a through the gas supply holes 250c. The gas supply holes 250a through the gas supply holes 250c are provided from the lower portion toward the upper portion of the reaction tube 203.

A source material (also referred to as a “source gas”) is supplied into the process chamber 201 through the gas supply pipe 232a provided with the MFC 241a and the valve 243a and the nozzle 249a.

A reactant (also referred to as a “first reactive gas”) is supplied into the process chamber 201 through the gas supply pipe 232b provided with the MFC 241b and the valve 243b and the nozzle 249b. For example, a gas containing nitrogen (N) and hydrogen (H) (also referred to as a N- and H-containing gas) may be used as the first reactive gas supplied through the gas supply pipe 232b. The N- and H-containing gas may act as a nitrogen source (which is a nitriding gas or a nitriding agent).

Another reactant (also referred to as a “second reactive gas”) is supplied into the process chamber 201 through the gas supply pipe 232c provided with the MFC 241c and the valve 243c and the nozzle 249c. For example, an oxygen (O)-containing gas may be used as the second reactive gas supplied through the gas supply pipe 232c. The oxygen-containing gas may act as an oxygen source (which is an oxidizing gas or an oxidizing agent).

An inert gas is supplied into the process chamber 201 via the gas supply pipes 232d through 232f provided with the MFCs 241d through 241f and the valves 243d through 243f, respectively, the gas supply pipes 232a through 232c and the nozzles 249a through 249c. The inert gas may act as a purge gas, a carrier gas, a dilution gas and the like. As will be described later, the inert gas may be supplied into the process chamber 201 by being excited into a plasma state within the process chamber 201. In such a case, the inert gas may also act as a modification gas.

A source gas supplier (which is a source gas supply structure or a source gas supply system) is constituted mainly by the gas supply pipe 232a, the MFC 241a and the valve 243a. A first reactive gas supplier (which is a first reactive gas supply structure or a first reactive gas supply system) is constituted mainly by the gas supply pipe 232b, the MFC 241b and the valve 243b. The first reactive gas supplier may also be referred to as a N- and H-containing gas supplier (which is a N- and H-containing gas supply structure or a N- and H-containing gas supply system). A second reactive gas supplier (which is a second reactive gas supply structure or a second reactive gas supply system) is constituted mainly by the gas supply pipe 232c, the MFC 241c and the valve 243c. The second reactive gas supplier may also be referred to as an oxygen-containing gas supplier (which is an oxygen-containing gas supply structure or an oxygen-containing gas supply system). Further, an inert gas supplier (which is an inert gas supply structure or an inert gas supply system) is constituted mainly by the gas supply pipes 232d through 232f, the MFCs 241d through 241f and the valves 243d through 243f. In a case where the inert gas acts as the modification gas as described above, the inert gas supplier may also be referred to as a modification gas supplier (which is a modification gas supply structure or a modification gas supply system).

Any one or an entirety of the gas suppliers described above may be embodied as an integrated gas supply system 248 in which the components such as the valves 243a through 243f and the MFCs 241a through 241f are integrated. The integrated gas supply system 248 is connected to each of the gas supply pipes 232a through 232f. An operation of the integrated gas supply system 248 to supply various gases to the gas supply pipes 232a through 232f, for example, operations such as an operation of opening and closing the valves 243a through 243f and an operation of adjusting flow rates of the gases through the MFCs 241a through 241f may be controlled by a controller 121 which will be described later. The integrated gas supply system 248 may be embodied as an integrated structure (integrated unit) of an all-in-one type or a divided type. The integrated gas supply system 248 may be attached to or detached from the components such as the gas supply pipes 232a through 232f on a basis of the integrated structure. Operations such as maintenance, replacement and addition for the integrated gas supply system 248 may be performed on a basis of the integrated structure.

The exhaust port 231a through which an inner atmosphere of the process chamber 201 is exhausted is provided at a lower side wall of the reaction tube 203. As shown in FIG. 2, the exhaust port 231a is arranged at a location so as to face the nozzles 249a through 249c (the gas supply holes 250a through the gas supply holes 250e) with the wafer 200 interposed therebetween when viewed from above. The exhaust port 231a may be provided so as to extend upward from the lower portion toward the upper portion of the reaction tube 203 along a side wall of the reaction tube 203 (that is, along the wafer arrangement region). An exhaust pipe 231 is connected to the exhaust port 231a. For example, the exhaust pipe 231 is made of a metal material such as SUS. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (pressure detection structure) to detect an inner pressure of the process chamber 201, and the APC valve 244 serves as a pressure regulator (pressure adjusting structure). With the vacuum pump 246 in operation, the APC valve 244 may be opened or closed to perform a vacuum exhaust operation of the process chamber 201 or stop the vacuum exhaust operation. With the vacuum pump 246 in operation, the inner pressure of the process chamber 201 may be adjusted by adjusting an opening degree of the APC valve 244 based on pressure information detected by the pressure sensor 245. The APC valve 244 may also be referred to as an “exhaust valve”. An exhauster (which is an exhaust structure or an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly sealing (or closing) a lower end opening of the manifold 209 is provided under the manifold 209. For example, the seal cap 219 is made of a metal material such as SUS, and is of a disk shape. An O-ring 220b serving as a seal is provided on an upper surface of the seal cap 219 so as to be in contact with the lower end of the manifold 209. A rotator 267 configured to rotate a boat 217 described later is provided under the seal cap 219. For example, a rotating shaft 255 of the rotator 267 is made of a metal material such as SUS, and is connected to the boat 217 through the seal cap 219. As the rotator 267 rotates the boat 217, the wafers 200 accommodated in the boat 217 are rotated. The seal cap 219 is elevated or lowered in the vertical direction by a boat elevator 115 serving as an elevating structure provided outside the reaction tube 203. The boat elevator 115 serves as a transfer device (which is a transfer structure or a transfer system) capable of transferring (loading) the boat 217 and the wafers 200 accommodated therein into the process chamber 201 and capable of transferring (unloading) the boat 217 and the wafers 200 accommodated therein out of the process chamber 201 by elevating and lowering the seal cap 219.

A shutter 219s serving as a furnace opening lid capable of airtightly sealing (or closing) the lower end opening of the manifold 209 is provided under the manifold 209. The shutter 219s is configured to close the lower end opening of the manifold 209 when the seal cap 219 is lowered by the boat elevator 115 and the boat 217 is unloaded out of the process chamber 201. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

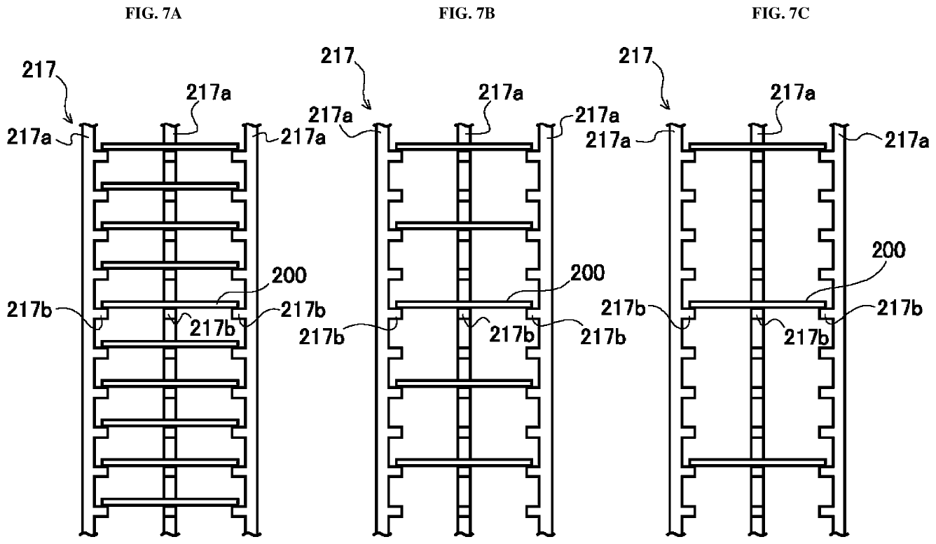

The boat 217 (which is a substrate support or a substrate retainer) is configured such that the wafers 200 (for example, 25 wafers to 200 wafers) are accommodated (or supported) in the vertical direction in the boat 217 while the wafers 200 are horizontally oriented with their centers aligned with one another in a multistage manner. That is, the boat 217 is configured such that the wafers 200 are arranged in the vertical direction in the boat 217 while the wafers 200 are horizontally oriented with a predetermined interval therebetween. For example, the boat 217 is made of a heat resistant material such as quartz and SiC. For example, a plurality of heat insulation plates 218 made of a heat resistant material such as quartz and SiC are supported at a lower portion of the boat 217 in a multistage manner. As shown in FIGS. 7A through 7C, the boat 217 is provided with a plurality of support columns 217a (for example, 3 support columns to 4 support columns) and a plurality of support structures 217b provided on each of the support columns 217a. Further, the boat 217 is configured such that the wafers 200 can be supported by the support structures 217b, respectively.

A temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. The temperature sensor 263 is provided along the inner wall of the reaction tube 203.

An electrode 300 for generating a plasma is provided outside the reaction tube 203, that is, outside the process vessel (process chamber 201). The electrode 300 is configured such that, by applying a power to the electrode 300, the gas inside the reaction tube 203 (that is, inside the process vessel (process chamber 201)) can be plasmatized and excited, that is, the gas can be excited into a plasma state. Hereinafter, an excitation of the gas into the plasma state may also be simply referred to as a “plasma excitation”. The electrode 300 is configured such that, by exciting the gas into the plasma state by simply applying the electric power to the electrode 300, a capacitively coupled plasma (abbreviated as CCP) serving as the plasma is generated inside the reaction tube 203, that is, inside the process vessel (process chamber 201).

Specifically, as shown in FIG. 2, the electrode 300 and an electrode fixture 301 configured to fix the electrode 300 are arranged between the heater 207 and the reaction tube 203. The electrode fixture 301 is provided in the inner side of the heater 207, and the electrode 300 is provided in an inner side of the electrode fixture 301. Further, the reaction tube 203 is provided in an inner side of the electrode 300.

In addition, as shown in FIGS. 1 and 2, each of the electrode 300 and the electrode fixture 301 is installed in an annular space provided between an inner wall of the heater 207 and an outer wall of the reaction tube 203 when viewed from above, and extends upward from the lower portion toward the upper portion of the reaction tube 203 along the outer wall of the reaction tube 203 (that is, extends upward along the arrangement direction of the wafers 200). The electrode 300 is provided parallel to the nozzles 249a through 249c. Each of the electrode 300 and the electrode fixture 301 is arranged in an arc shape when viewed from above to be aligned in a manner concentric with the reaction tube 203 and the heater 207, and is not in contact with the reaction tube 203 and the heater 207. For example, the electrode fixture 301 is made of an insulating material (insulator), and is provided so as to cover at least a part of the electrode 300 and the reaction tube 203. Therefore, the electrode fixture 301 may also be referred to as a “cover” (which is a quartz cover, an insulating wall or an insulating plate) or a “cover with an arc-shaped cross-section” (which is a body with an arc-shaped cross-section or a wall with an arc-shaped cross-section).

As shown in FIG. 2, a plurality of electrodes constituting the electrode 300 are provided. Hereinafter, the plurality of electrodes constituting the electrode 300 may also be simply referred to as “electrodes 300”. The electrodes 300 are fixed and installed on an inner wall of the electrode fixture 301. More specifically, as shown in FIG. 4, a plurality of protrusions (which are hooks) 301a on which the electrodes 300 can be hooked are provided on a surface of the inner wall of the electrode fixture 301. Further, a plurality of openings 300c which are through-holes through which the protrusions 301a can be inserted are provided at the electrodes 300. The electrodes 300 can be fixed to the electrode fixture 301 by hooking the electrodes 300 on the protrusions 301a provided on the surface of the inner wall of the electrode fixture 301 through the openings 300c. In FIG. 4, an example of fixing one of the electrodes 300 at two locations (that is, two openings 300c are provided for the one of the electrodes 300, and the one of the electrodes 300 is hooked at and fixed by the two protrusions 301a) is shown. In FIG. 2, an example in which nine electrodes 300 are fixed to the electrode fixture 301 is shown. In addition, in FIG. 4, an example in which twelve electrodes 300 are fixed to the electrode fixture 301 is shown.

Each of the electrodes 300 is made of an oxidation resistant material such as nickel (Ni). Each of the electrodes 300 may be made of a metal material such as SUS, aluminum (Al) and copper (Cu). However, when each of the electrodes 300 is made of the oxidation resistant material such as nickel (Ni), it is possible to suppress a deterioration of an electrical conductivity, and it is also possible to suppress a decrease in an efficiency of generating the plasma. Furthermore, each of the electrodes 300 may also be made of a nickel alloy material to which aluminum (Al) is added. In such a case, an aluminum oxide film (also referred to as an “AlO film”) (which is an oxide film with high heat resistance and high corrosion resistance) may be formed on an outermost surface of each of the electrodes 300. The AlO film formed on the outermost surface of each of the electrodes 300 acts as a protective film (which is a block film or a barrier film), and can suppress a progress of the deterioration inside each of the electrodes 300. Thereby, it is possible to further suppress the decrease in the efficiency of generating the plasma due to a decrease in the electrical conductivity of each of the electrodes 300. The electrode fixture 301 is made of an insulating material (insulator), for example, a heat resistant material such as quartz and SiC. It is preferable that the material of the electrode fixture 301 is the same as that of the reaction tube 203.

As shown in FIG. 2, the electrodes 300 may include a first type electrode 300a and a second type electrode 300b. The first type electrode 300a is connected to a high frequency power supply (also referred to as an “RF power supply”) 320 via a matcher (which is a matching structure) 305. The second type electrode 300b is grounded, and serves as a reference potential (0 V). The first type electrode 300a may also be referred to as a “hot electrode” or a “HOT electrode)”, and the second type electrode 300b may also be referred to as a “ground electrode” or a “GND electrode”. Each of the first type electrode 300a and the second type electrode 300b is configured as a plate-shaped structure of a rectangular shape when viewed from front. According to the present embodiments, for example, one or more first type electrodes including the first type electrode 300a are provided and one or more second type electrodes including the second type electrode 300b are provided. In FIGS. 1, 2, and 4, an example in which a plurality of first type electrodes including the first type electrode 300a are provided and a plurality of second type electrodes including the second type electrode 300b are provided is shown. In FIG. 2, an example in which the electrode fixture 301 is provided with six first type electrodes 300a and three second type electrodes 300b is shown. Further, in FIG. 4, an example in which the electrode fixture 301 is provided with eight first type electrodes 300a and four second type electrodes 300b is shown. By applying an RF power between the first type electrode 300a and the second type electrode 300b from the RF power supply 320 via the matcher 305, the plasma is generated in a region between the first type electrode 300a and the second type electrode 300b. The region between the first type electrode 300a and the second type electrode 300b described above may also be referred to as a “plasma generation region”.

It is preferable that a surface area of the first type electrode 300a is preferably two to three times a surface area of the second type electrode 300b. In a case where the surface area of the first type electrode 300a is less than twice the surface area of the second type electrode 300b, an electric potential distribution becomes narrow, and the efficiency of generating the plasma may decrease. In a case where the surface area of the first type electrode 300a exceeds three times the surface area of the second type electrode 300b, the electric potential distribution may extend to an edge of the wafer 200, and the wafer 200 may serve as an obstacle to saturate the efficiency of generating the plasma. Further, in such a case, a discharge may also occur at the edge of the wafer 200. As a result, the plasma damage to the wafer 200 may occur. By setting the surface area of the first type electrode 300a to be two to three times the surface area of the second type electrode 300b, it is possible to increase the efficiency of generating the plasma and it is also possible to suppress the plasma damage to the wafer 200. Further, as shown in FIG. 2, the electrodes 300 (the first type electrode 300a and the second type electrode 300b) are in an arc shape when viewed from above, and are arranged at equal intervals, that is, the electrodes 300 (the first type electrode 300a and the second type electrode 300b) are arranged such that a distance (gap) between each adjacent electrode is the same. In addition, as described above, the electrodes 300 (the first type electrode 300a and the second type electrode 300b) are provided parallel to the nozzles 249a through 249c.

In the present embodiments, the electrode fixture 301 and the electrodes 300 (the first type electrode 300a and the second type electrode 300b) may also be collectively referred to as an “electrode structure”. The electrode structure is preferably arranged at a location that can avoid contact with the nozzles 249a through 249c, the temperature sensor 263, the exhaust port 231a and the exhaust pipe 231, as shown in FIG. 2. In FIG. 2, an example in which two electrode structures are arranged to face each other via the centers of the wafers 200 (that is, a center of the reaction tube 203) interposed therebetween while avoiding contact with the nozzles 249a through 249c, the temperature sensor 263, the exhaust port 231a and the exhaust pipe 231 is shown. In the example shown in FIG. 2, the two electrode structures are arranged line-symmetrically, when viewed from above, with respect to the straight line L serving as the axis of symmetry (that is, the two electrode structures are arranged symmetrically with each other). By arranging the electrode structures as described above, it is possible to arrange the nozzles 249a through 249c, the temperature sensor 263, the exhaust port 231a and the exhaust pipe 231 outside the plasma generation region in the process chamber 201. Thereby, it is possible to suppress a plasma damage to components (that is, the nozzles 249a through 249c, the temperature sensor 263, the exhaust port 231a and the exhaust pipe 231), a wear and tear of the components described above and a generation of particles from the components described above.

A plasma exciter (which is a plasma exciting structure, a plasma activator or a plasma activating structure) capable of exciting (or activating) the gas into the plasma state is constituted mainly by the electrodes 300 (that is, the first type electrode 300a and the second type electrode 300b). The plasma exciter may further include the electrode fixture 301, the matcher 305 and the RF power supply 320.

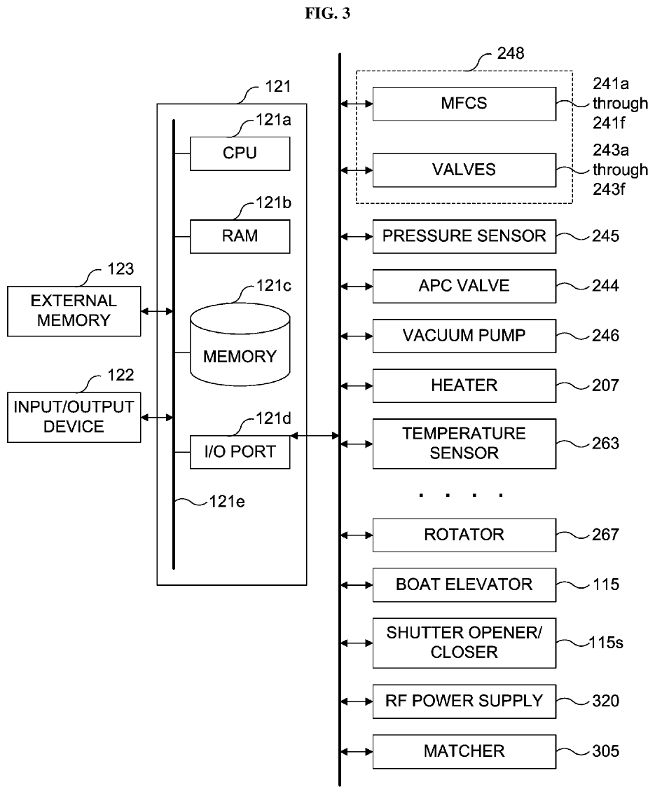

As shown in FIG. 3, the controller 121 serving as a control device (control structure) is constituted by a computer including a CPU (Central Processing Unit) 121a, a RAM (Random Access Memory) 121b, a memory 121c and an I/O port (input/output port) 121d. The RAM 121b, the memory 121c and the I/O port 121d may exchange data with the CPU 121a through an internal bus 121e. For example, an input/output device 122 constituted by a component such as a touch panel is connected to the controller 121. Further, the controller 121 is configured to be capable of being connected to an external memory 123.

The memory 121c is configured by a component such as a flash memory, a hard disk drive (HDD) and a solid state drive (SSD). For example, a control program configured to control an operation of the substrate processing apparatus and a process recipe containing information on sequences and conditions of a substrate processing described later may be readably stored in the memory 121c. The process recipe is obtained by combining steps (sequences or processes) of the substrate processing described later such that the controller 121 can execute the steps to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the recipe alone, may refer to the control program alone or may refer to both of the recipe and the control program. The RAM 121b functions as a memory area (work area) where a program or data read by the CPU 121a is temporarily stored.

The I/O port 121d is connected to the components described above such as the MFCs 241a through 241f, the valves 243a through 243f, the pressure sensor 245, the APC valve 244, the vacuum pump 246, the temperature sensor 263, the heater 207, the rotator 267, the boat elevator 115, the shutter opener/closer 115s, the RF power supply 320 and the matcher 305.

The CPU 121a is configured to read the control program from the memory 121c and execute the read control program. In addition, the CPU 121a is configured to read the recipe from the memory 121c, for example, in accordance with an operation command inputted from the input/output device 122. In accordance with contents of the read recipe, the CPU 121a may be configured to be capable of controlling various operations such as flow rate adjusting operations for various gases by the MFCs 241a through 241f, opening and closing operations of the valves 243a through 243f, an opening and closing operation of the APC valve 244, a pressure regulating operation (pressure adjusting operation) by the APC valve 244 based on the pressure sensor 245, a start and stop operation of the vacuum pump 246, a temperature adjusting operation by the heater 207 based on the temperature sensor 263, an operation of adjusting a rotation and a rotation speed of the boat 217 by the rotator 267, an elevating and lowering operation of the boat 217 by the boat elevator 115, an opening and closing operation of the shutter 219s by the shutter opener/closer 115s, an impedance adjusting operation (impedance matching operation) by the matcher 305 and a power supply operation to the RF power supply 320.

The controller 121 may be embodied by installing the above-described program stored in the external memory 123 into the computer. For example, the external memory 123 may include a magnetic disk such as the HDD, an optical disk such as a CD, a magneto-optical disk such as an MO and a semiconductor memory such as a USB memory and the SSD. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123. Instead of the external memory 123, a communication structure such as the Internet and a dedicated line may be used for providing the program to the computer.

### (2) SUBSTRATE PROCESSING

Hereinafter, an example of a process sequence (that is, a film-forming sequence) of the substrate processing of forming a film on the wafer 200 serving as the substrate by using the substrate processing apparatus described above, which is a part of a manufacturing process of a semiconductor device, will be described. For example, according to the process sequence, a nitride film serving an insulating film is formed on the wafer 200 as the film. In the following descriptions, operations of components constituting the substrate processing apparatus are controlled by the controller 121.

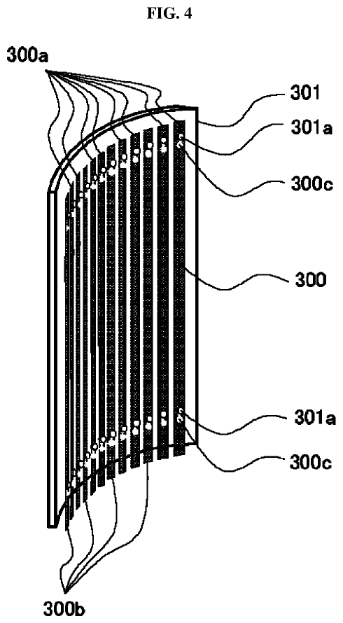

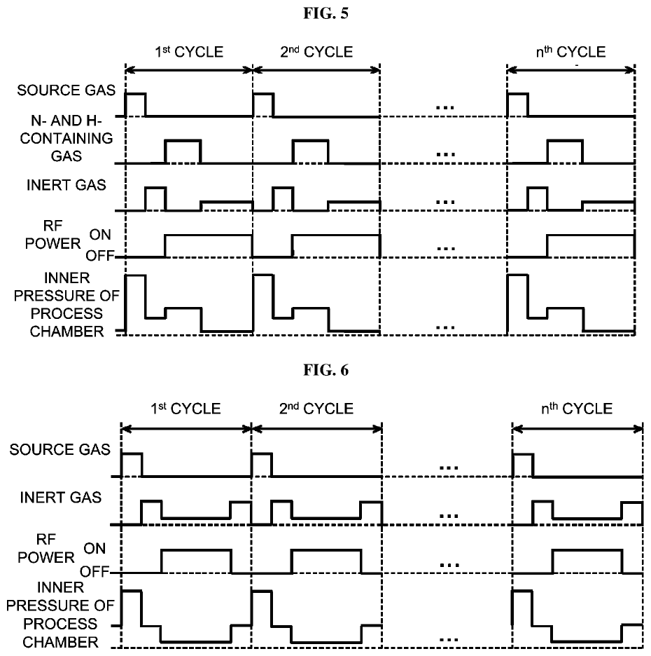

In the process sequence according to the present embodiments as shown in FIG. 5, the film is formed on the wafer 200 by performing a cycle a predetermined number of times (n times, where n is an integer of 1 or more). The cycle may include: (a) supplying the source gas to the wafer 200 in the process vessel; (b) supplying the plasma-excited N- and H-containing gas to the wafer 200 in the process vessel by exciting the N- and H-containing gas into the plasma state; and (c) supplying the plasma-excited inert gas to the wafer 200 in the process vessel by exciting the inert gas into the plasma state, and an inner pressure of the process vessel (that is, a pressure of a space where the wafer 200 is present) in (c) is set to be lower than the inner pressure of the process vessel in (b). In the cycle, (a), (b) and (c) are performed non-simultaneously.

In the present specification, such a process sequence of the substrate processing may be illustrated as follows. Process sequences of modified examples and other embodiments, which will be described later, will be also represented in the same manner.

(Source gas→Plasma-excited N- and H-containing gas→Plasma-excited inert gas)×n

In FIG. 5, an example in which the inner pressure of the process vessel in (c) is set to be lower than the inner pressure of the process vessel in (a) is shown. Further, in FIG. 5, an example in which the inner pressure of the process vessel in (c) is set to be lower than the inner pressure of the process vessel in (b) and the inner pressure of the process vessel in (b) is set to be lower than the inner pressure of the process vessel in (a) is shown.

In addition, in FIG. 5, an example in which a supply time (time duration) of supplying the plasma-excited inert gas by exciting the inert gas into the plasma state in (c) is set to be longer than a supply time (time duration) of supplying the plasma-excited N- and H-containing gas by exciting the N- and H-containing gas into the plasma state in (b) is shown, and an example in which the supply time (time duration) of supplying the plasma-excited inert gas by exciting the inert gas into the plasma state in (c) is set to be longer than a supply time (time duration) of supplying the source gas in (a) is shown. More specifically, FIG. 5 shows an example in which the supply time (time duration) of supplying the plasma-excited inert gas by exciting the inert gas into the plasma state in (c) is set to be longer than the supply time (time duration) of supplying the plasma-excited N- and H-containing gas by exciting the N- and H-containing gas into the plasma state in (b) and the supply time (time duration) of supplying the plasma-excited N- and H-containing gas by exciting the N- and H-containing gas into the plasma state in (b) is set to be longer than the supply time (time duration) of supplying the source gas in (a).

In the process sequence shown in FIG. 5, an example in which the cycle of performing (a), (b) and (c) in this order is repeatedly performed a plurality of times (n times) is shown. In such a case, n is an integer of 2 or more. In FIG. 5, an example in which the inner atmosphere of the process vessel is purged with the inert gas in a non-plasma atmosphere after performing (a) and before performing (b) is shown. Further, after performing (b) and before performing (c), the inner atmosphere of the process vessel may be purged with the inert gas in the non-plasma atmosphere. Further, in a case where the cycle is performed a plurality of times, after performing (c) and before performing (a), the inner atmosphere of the process vessel may be purged with the inert gas in the non-plasma atmosphere. As a result, it is possible to suppress phenomena such as a mixture of each gas, an unintended reaction due to the mixture and the generation of the particles. Process sequences corresponding to examples described above may be illustrated as follows. In the following descriptions, “P” represents a purge performed in the non-plasma atmosphere.

(Source gas→P→Plasma-excited N- and H-containing gas→Plasma-excited inert gas)×n

(Source gas→P→Plasma-excited N- and H-containing gas→P→Plasma-excited inert gas)×n

(Source gas→P→Plasma-excited N- and H-containing gas→Plasma-excited inert gas→P)×n

(Source gas→P→Plasma-excited N- and H-containing gas→P→Plasma-excited inert gas→P)×n

For example, in (b), it is preferable to excite the N- and H-containing gas into the plasma state in the process vessel by applying the power to the electrode 300 provided outside the process chamber vessel. Further, for example, in (c), it is preferable to excite the inert gas into the plasma state in the process vessel by applying the power to the electrode 300 provided outside the process vessel.

For example, in (a), it is preferable supply the source gas to the wafer 200 through the edge (side portion) of the wafer 200. Further, for example, in (b), it is preferable supply the plasma-excited N- and H-containing gas to the wafer 200 through the edge (side portion) of the wafer 200 by exciting the N- and H-containing gas into the plasma state. Further, for example, in (c), it is preferable supply the plasma-excited inert gas to the wafer 200 through the edge (side portion) of the wafer 200 by exciting the inert gas into the plasma state.

Hereinafter, an example in which the nitride film is formed as the film will be described. In the present embodiments, the “nitride film” may include not only a silicon nitride film (SiN film) but also a nitride film containing carbon (C), oxygen (O), boron (B) and the like. That is the “nitride film” may refer to a film such as the silicon nitride film (SiN film), a silicon carbonitride film (SiCN film), a silicon oxynitride film (SiON film), a silicon oxycarbonitride film (SiOCN film), a silicon borocarbonitride film (SiBCN film), a silicon boronitride film (SiBN film), a silicon borocarbonitride film (SiBOCN film) and a silicon borooxynitride film (SiBON film). Hereinafter, an example in which the SiN film is formed as the film will be described.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

### <Wafer Charging Step>

The wafers 200 are charged (transferred) into the boat 217 (wafer charging step). Thereafter, the shutter 219s is moved by the shutter opener/closer 115s to open the lower end opening of the manifold 209 (shutter opening step). The wafer 200 may refer to a product wafer and/or a dummy wafer.

### <Boat Loading Step>

Thereafter, as shown in FIG. 1, the boat 217 supporting the wafers 200 is elevated by the boat elevator 115 and loaded (transferred) into the process chamber 201 (boat loading step). With the boat 217 loaded, the seal cap 219 airtightly seals the lower end of the manifold 209 via the O-ring 220b.

### <Pressure Adjusting Step and Temperature Adjusting Step>

Thereafter, the vacuum pump 246 vacuum-exhausts (decompresses and exhausts) the inner atmosphere of the process chamber 201 (that is, a space in which the wafers 200 are present (accommodated)) such that the inner pressure of the process chamber 201 reaches and is maintained at a desired pressure (vacuum degree). When the vacuum pump 246 vacuum-exhausts the inner atmosphere of the process chamber 201, the inner pressure of the process chamber 201 is measured by the pressure sensor 245, and the APC valve 244 is feedback-controlled based on the pressure information detected by the pressure sensor 245 (pressure adjusting step). In addition, the heater 207 heats the process chamber 201 such that a temperature of the wafer 200 in the process chamber 201 reaches and is maintained at a desired process temperature. When the heater 207 heats the process chamber 201, the state of the electric conduction to the heater 207 is feedback-controlled based on the temperature information detected by the temperature sensor 263 such that a desired temperature distribution of the inner temperature of the process chamber 201 can be obtained (temperature adjusting step). In addition, a rotation of the wafer 200 is started by the rotator 267. The vacuum pump 246 continuously vacuum-exhausts the inner atmosphere of the process chamber 201, the heater 207 continuously heats the wafer 200 in the process chamber 201 and the rotator 267 continuously rotates the wafer 200 until at least a processing of the wafer 200 is completed.

### <Film-Forming Step>

Thereafter, the film-forming step is performed by sequentially performing a first step, a second step and a third step.

### <First Step>

In the first step, the source gas is supplied onto the wafers 200 in the process chamber 201.

Specifically, the valve 243a is opened to supply the source gas into the gas supply pipe 232a. After a flow rate of the source gas is adjusted by the MFC 241a, the source gas whose flow rate is adjusted is supplied into the process chamber 201 through the nozzle 249a, and is exhausted through the exhaust port 231a. Thereby, the source gas is supplied onto the wafers 200 through edges (side portions) of the wafers 200 (source gas supply). In the present step, the valves 243d through 243f may be opened to supply the inert gas into the process chamber 201 through each of the nozzles 249a through 249c.

For example, process conditions of the present step are as follows:
A process temperature: from 250° C. to 550° C., preferably from 400° C. to 500° C.;
A process pressure: from 100 Pa to 4,000 Pa, preferably from 100 Pa to 1,000 Pa;
A supply flow rate of the source gas: from 0.1 slm to 3 slm;
A supply time (time duration) of supplying the source gas: from 1 second to 100 seconds, preferably from 1 second to 30 seconds; and
A supply flow rate of the inert gas (for each gas supply pipe): from 0 slm to 10 slm.

Further, in the present specification, a notation of a numerical range such as “from 250° C. to 550° C.” means that a lower limit and an upper limit are included in the numerical range. Therefore, for example, a numerical range “from 250° C. to 550° C.” means a range equal to or higher than 250° C. and equal to or lower than 550° C. The same also applies to other numerical ranges described herein. For example, in the present specification, the process temperature refers to a temperature of the wafer 200 or the inner temperature of the process chamber 201, and the process pressure refers to the inner pressure of the process chamber 201. Further, when the supply flow rate of the gas is 0 slm, it means a case where the gas is not supplied. The same also applies to the following descriptions.

By supplying the source gas (for example, a chlorosilane-based gas) to the wafers 200 the process chamber 201 in accordance with the process conditions described above, a silicon (Si)-containing layer containing chlorine (Cl) is formed on an uppermost surface of the wafer 200 serving as a base. For example, the silicon-containing layer containing chlorine may be formed by a physical adsorption or a chemical adsorption of molecules of the chlorosilane-based gas onto the uppermost surface of the wafer 200, a physical adsorption or a chemical adsorption of substances generated by decomposing a part of the molecules of the chlorosilane-based gas onto the uppermost surface of the wafer 200, a deposition of silicon onto the uppermost surface of the wafer 200 due to a thermal decomposition of the chlorosilane-based gas and the like. That is, the silicon-containing layer containing chlorine may be an adsorption layer (a physical adsorption layer or a chemical adsorption layer) of the molecules of the chlorosilane-based gas or the substances generated by decomposing a part of the molecules of the chlorosilane-based gas, or may be a deposition layer of silicon containing chlorine. In the present specification, the silicon-containing layer containing chlorine may also be simply referred to as a “silicon-containing layer”. Under the process conditions described above, the physical adsorption or the chemical adsorption of the molecules of the chlorosilane-based gas (or the substances generated by decomposing a part of the molecules of the chlorosilane-based gas) onto the uppermost surface of the wafer 200 dominantly (primarily) occurs, and the deposition of silicon due to the thermal decomposition of the chlorosilane-based gas negligibly or hardly occurs. That is, under the process conditions described above, the silicon-containing layer contains an overwhelmingly large amount of the adsorption layer (the physical adsorption layer or the chemical adsorption layer) of the molecules of the chlorosilane-based gas (or the substances generated by decomposing a part of the molecules of the chlorosilane-based gas), and contains a small amount of the deposition layer of silicon containing chlorine (or hardly contains the deposition layer of silicon containing chlorine).

After the silicon-containing layer is formed, the valve 243a is closed to stop a supply of the source gas into the process chamber 201. Then, the vacuum pump 246 vacuum-exhausts the inner atmosphere of the process chamber 201 to remove a substance such as a residual gas remaining in the process chamber 201 from the process chamber 201 (purge). When exhausting the inner atmosphere of the process chamber 201, by opening the valves 243d through 243f, the inert gas is supplied into the process chamber 201. The inert gas acts as the purge gas. The inner atmosphere of the process chamber 201 is purged with the inert gas in the non-plasma atmosphere. As a result, it is possible to suppress phenomena such as a mixture of the source gas remaining in the process chamber 201 and the N- and H-containing gas supplied into the process chamber 201 in the second step, an unintended reaction due to the mixture (for example, a gas phase reaction or a plasma gas phase reaction) and the generation of the particles.

For example, process conditions of the purge are as follows:
A process temperature: from 250° C. to 550° C., preferably from 400° C. to 500° C.;
A process pressure: from 1 Pa to 20 Pa;
A supply flow rate of the inert gas (for each gas supply pipe): from 0.05 slm to 20 slm; and
A supply time (time duration) of supplying the inert gas: from 1 second to 600 seconds, preferably from 1 second to 40 seconds.

As the source gas, for example, a silane-based gas containing silicon (Si) serving as a main element (primary element) constituting the film formed on the wafer 200 may be used. As the silane-based gas, for example, a gas containing silicon and a halogen element, that is, a halosilane-based gas may be used. The halogen element includes an element such as chlorine (Cl), fluorine (F), bromine (Br) and iodine (I). As the halosilane-based gas, for example, the chlorosilane-based gas containing silicon and chlorine may be used as described above.

For example, the chlorosilane-based gas such as monochlorosilane (SiH3Cl, abbreviated as MCS) gas, dichlorosilane (SiH2Cl2, abbreviated as DCS) gas, trichlorosilane (SiHCl3, abbreviated as TCS) gas, tetrachlorosilane (SiCl4, abbreviated as 4CS) gas, hexachlorodisilane (Si2Cl6, abbreviated as HCDS) gas and octachlorotrisilane (Si3Cl8, abbreviated as OCTS) gas may be used as the source gas. For example, one or more of the gases exemplified above as the chlorosilane-based gas may be used as the source gas.

Further, for example, instead of or in addition to the chlorosilane-based, a fluorosilane-based gas such as tetrafluorosilane (SiF4) gas and difluorosilane (SiH2F2) gas, a bromosilane-based gas such as tetrabromosilane (SiBr4) gas and dibromosilane (SiH2Br2) gas, or an iodine silane-based gas such as tetraiodide silane (SiI4) gas and diiodosilane (SiH2I2) gas may be used as the source gas. For example, one or more of the gases exemplified above may be used as the source gas.

For example, instead of or in addition to the gases exemplified above, a gas containing silicon and an amino group, that is, an aminosilane-based gas may be used as the source gas. The amino group refers to a monovalent functional group obtained by removing hydrogen (H) from ammonia, a primary amine or a secondary amine, and may be expressed as “—NH2”, “—NHR” or “—NR2”. In addition, “R” represents an alkyl group, and two “R”s of “—NR2” may be the same or different.

For example, the aminosilane-based gas such as tetrakis (dimethylamino) silane (Si[N(CH3)2]4, abbreviated as 4DMAS) gas, tris (dimethylamino) silane (Si[N(CH3)2]3H, abbreviated as 3DMAS) gas, bis (diethylamino) silane (Si[N(C2H5)2]2H2, abbreviated as BDEAS) gas, bis (tertiarybutylamino) silane gas (SiH2[NH(C4H9)]2, abbreviated as BTBAS) and (diisopropylamino) silane (SiH3[N(C3H7)2], abbreviated as DIPAS) gas may be used as the source gas. For example, one or more of the gases exemplified above as the aminosilane-based gas may be used as the source gas.

For example, a nitrogen (N2) gas or a rare gas such as argon (Ar) gas, helium (He) gas, neon (Ne) gas, xenon (Xe), krypton (Kr) gas and radon (Rn) gas may be used as the inert gas. For example, one or more of the gases exemplified above as the inert gas may be used as the inert gas. The same also applies to each step described later.

### <Second Step>

After the first step is completed, the N- and H-containing gas excited into the plasma state is supplied onto the wafers 200 in the process chamber 201, that is, the silicon-containing layer formed on the wafers 200.

Specifically, the valve 243b is opened to supply the N- and H-containing gas into the gas supply pipe 232b. After a flow rate of the N- and H-containing gas is adjusted by the MFC 241b, the N- and H-containing gas whose flow rate is adjusted is supplied into the process chamber 201 through the nozzle 249b, and is exhausted through the exhaust port 231a. Thereby, the N- and H-containing gas is supplied onto the wafers 200 through the edges (side portions) of the wafers 200 (N- and H-containing gas supply). In the present step, the valves 243d through 243f may be opened to supply the inert gas into the process chamber 201 through each of the nozzles 249a through 249c.

In the present step, by applying the RF power between the first type electrode 300a and the second type electrode 300b, the plasma is generated in the region between the first type electrode 300a and the second type electrode 300b. As a result, the N- and H-containing gas is excited into the plasma state, and active species such as NHx* (where x is an integer of 1 to 3) are generated and supplied to the wafers 200 (plasma-excited N- and H-containing gas supply). Thereby, the N- and H-containing gas and containing the active species such as NH*, NH2* and NH3* is supplied onto the wafers 200. In the present specification, the symbol “*” refers to a radical. The same also applies to the following descriptions.

Alternatively, before supplying the plasma-excited N- and H-containing gas to the wafers 200 by exciting the N- and H-containing gas into the plasma state, a period may be provided in which the N- and H-containing gas is supplied without being excited into the plasma state. That is, before the N- and H-containing gas (which is plasma-excited) is supplied to the wafers 200, the N- and H-containing gas (which is non-plasma-excited) may be supplied, that is, the N- and H-containing gas (which is non-plasma-excited) may be preflowed (non-plasma-excited N- and H-containing gas preflow). In such as case, first, the N- and H-containing gas is supplied without being excited into the plasma state, and after a predetermined period of time has elapsed, the RF power may be applied between the first type electrode 300a and the second type electrode 300b while the N- and H-containing gas is continuously supplied. Thereby, it is possible to more stably generate the plasma or the active species.

For example, process conditions of the present step are as follows:
A process temperature: from 250° C. to 550° C., preferably from 400° C. to 500° C.;
A process pressure: from 2 Pa to 100 Pa, preferably from 20 Pa to 70 Pa;
A supply flow rate of the N- and H-containing gas: from 0.1 slm to 10 slm;
A supply time (time duration) of supplying the N- and H-containing gas: from 10 seconds to 600 seconds, preferably from 1 second to 50 seconds; and
A supply flow rate of the inert gas (for each gas supply pipe): from 0 slm to 10 slm; The RF power: from 100 W to 1,000 W; and
A frequency of the RF power: 13.56 MHz or 27 MHz.

By supplying the plasma-excited N- and H-containing gas onto the wafer 200 by exciting the N- and H-containing gas into the plasma state in accordance with the process conditions described above, at least a part of the silicon-containing layer formed on the wafer 200 is nitride (modified). As a result, a silicon nitride layer (SiN layer) serving as a layer containing silicon (Si) and nitrogen (N) is formed on the uppermost surface of the wafer 200 serving as the base. When the SiN layer is formed, impurities such as chlorine contained in the silicon-containing layer may form a gas phase substance containing at least chlorine during a modifying reaction of the silicon-containing layer by the active species such as the NHx*, and the gas phase substance is discharged from the process chamber 201. As a result, the SiN layer becomes a layer which contains a smaller amount of the impurities such as chlorine than the silicon-containing layer formed in the first step.

After the SiN layer is formed, the valve 243b is closed to stop a supply of the N- and H-containing gas into the process chamber 201. Thereafter, the third step is performed. However, before the third step is performed, the inner atmosphere of the process chamber 201 may be purged in the non-plasma atmosphere. In such a case, a substance such as a residual gas remaining in the process chamber 201 is removed from the process chamber 201 according to the same sequence as those of the first step. As a result, it is possible to suppress phenomena such as a mixture of the N- and H-containing gas (which is plasma-excited) remaining in the process chamber 201 and the inert gas (which is plasma-excited) supplied into the process chamber 201 in the third step, an unintended reaction due to the mixture (for example, a plasma gas phase reaction) and the generation of the particles.

The N- and H-containing gas acts as the nitriding agent (which is the nitrogen source or the nitriding agent). The N- and H-containing gas may serve as a nitrogen (N)-containing gas, and may also serve as a hydrogen (H)-containing gas. It is preferable that the N- and H-containing gas contains a nitrogen (N)-hydrogen (H) bond.

As the N- and H-containing gas, for example, a hydrogen nitride gas such as ammonia (NH3) gas, diazene (N2H2) gas, hydrazine (N2H4) gas and N3H8 gas may be used. For example, one or more of the gases exemplified above as the N- and H-containing gas may be used as the N- and H-containing gas.

For example, instead of or in addition to the gases exemplified above as the N- and H-containing gas, a gas containing nitrogen (N), carbon (C) and hydrogen (H) may be used as the N- and H-containing gas. As the gas containing nitrogen, carbon and hydrogen, for example, an amine-based gas or an organic hydrazine-based gas may be used. The gas containing nitrogen, carbon and hydrogen may serve as a nitrogen (N)-containing gas, may serve as a carbon (C)-containing gas, may serve as a hydrogen (H)-containing gas or may serve as a gas containing nitrogen (N) and carbon (C).

As the N- and H-containing gas, for example, an ethylamine-based gas such as monoethylamine (C2H5NH2, abbreviated as MEA) gas, diethylamine ((C2H5)2NH, abbreviated as DEA) gas and triethylamine ((C2H5)3N, abbreviated as TEA) gas, a methylamine-based gas such as monomethylamine (CH3NH2, abbreviated as MMA) gas, dimethylamine ((CH3)2NH, abbreviated as DMA) gas and trimethylamine ((CH3)3N, abbreviated as TMA) gas, or an organic hydrazine-based gas such as monomethylhydrazine ((CH3)HN2H2, abbreviated as MMH) gas, dimethylhydrazine ((CH3)2N2H2, abbreviated as DMH) gas, trimethylhydrazine ((CH3)2N2(CH3)H, abbreviated as TMH) gas may be used. For example, one or more of the gases exemplified above as the N- and H-containing gas may be used as the N- and H-containing gas.

### <Third Step>

After the second step is completed, the inert gas excited into the plasma state is supplied onto the wafers 200 in the process chamber 201, that is, the SiN layer formed on the wafers 200.

Specifically, the valves 243d through 243f are opened to supply the inert gas into each of the gas supply pipes 232d through 232f. After a flow rate of the inert gas is adjusted by each of the MFCs 241d through 241f, the inert gas whose flow rate is adjusted is supplied into the process chamber 201 through each of the nozzles 249a through 249c, and is exhausted through the exhaust port 231a. Thereby, the inert gas is supplied onto the wafers 200 through the edges (side portions) of the wafers 200 (inert gas supply).

In the present step, by applying the RF power between the first type electrode 300a and the second type electrode 300b, the plasma is generated in the region between the first type electrode 300a and the second type electrode 300b. As a result, the inert gas is excited into the plasma state, and active species are generated and supplied to the wafers 200 (plasma-excited inert gas supply). Thereby, the plasma-excited inert gas containing the active species is supplied onto the wafers 200.

For example, in a case where the N2 gas is used as the inert gas, the N2 gas is excited into the plasma state, and active species such as Nx* (where x is an integer of 1 to 2) are generated and supplied to the wafers 200 (plasma-excited N2 gas supply). Thereby, the plasma-excited N2 gas containing the active species such as N* and N2* is supplied onto the wafers 200.

For example, in a case where the argon (Ar) gas is used as the inert gas, the Ar gas is excited into the plasma state, and active species such as Ar* are generated and supplied to the wafers 200 (plasma-excited Ar gas supply). Thereby, the plasma-excited Ar gas containing the active species such as Ar* is supplied onto the wafers 200.

For example, in a case where the helium (He) gas is used as the inert gas, the He gas is excited into the plasma state, and active species such as He* are generated and supplied to the wafers 200 (plasma-excited He gas supply). Thereby, the plasma-excited He gas containing the active species such as He* is supplied onto the wafers 200.

As the inert gas, a gaseous mixture (mixed gas) of the gases exemplified above as the inert gas mixed in the process chamber 201 may be used. For example, as the inert gas, a gaseous mixture of the N2 gas and the Ar gas may be used, a gaseous mixture of the N2 gas and the He gas may be used, or a gaseous mixture of the N2 gas the Ar gas and the He gas may be used.

Alternatively, before supplying the plasma-excited inert gas to the wafers 200 by exciting inert gas into the plasma state, a period may be provided in which the inert gas is supplied without being excited into the plasma state. That is, before the inert gas (which is plasma-excited) is supplied to the wafers 200, the inert gas (which is non-plasma-excited) may be supplied, that is, the inert gas (which is non-plasma-excited) may be preflowed (non-plasma-excited inert gas preflow). In such as case, first, the inert gas is supplied without being excited into the plasma state, and after a predetermined period of time has elapsed, the RF power may be applied between the first type electrode 300a and the second type electrode 300b while the inert gas is continuously supplied. Thereby, it is possible to more stably generate the plasma or the active species.

For example, process conditions of the present step are as follows:
A process temperature: from 250° C. to 550° C., preferably from 400° C. to 500° C.;
A process pressure: from 2 Pa to 6 Pa, preferably from 2.66 Pa to 5.32 Pa, more preferably from 3 Pa to 4 Pa;
A supply flow rate of the inert gas (for each gas supply pipe): from 0.01 slm to 2 slm;
A supply time (time duration) of supplying the inert gas: from 1 second to 600 seconds, preferably from 10 seconds to 60 seconds; and
The RF power: from 100 W to 1,000 W; and
The frequency of the RF power: 13.56 MHz or 27 MHz.

By supplying the plasma-excited inert gas onto the wafer 200 by exciting the inert gas into the plasma state in accordance with the process conditions described above, at least a part of the SiN layer formed on the wafer 200 is modified. When the SiN layer is modified, the impurities such as chlorine contained in the SiN layer may form a gas phase substance containing at least chlorine during a modifying reaction of the SiN layer by the active species, and the gas phase substance is discharged from the process chamber 201. As a result, the SiN layer after modified in the present step becomes a layer which contains a smaller amount of the impurities such as chlorine than the SiN layer formed in the second step. Further, by modifying the SiN layer in the present step, the SiN layer is densified. Thereby, a density of the SiN layer after modified in the present step is set to be higher than that of the SiN layer formed in the second step.

Further, by the modifying reaction by the active species such as the NHx* in the second step, a content of the impurities such as chlorine in the SiN layer formed in the second step can be reduced as compared with a content of the impurities such as chlorine in the silicon-containing layer formed in the first step. However, in the SiN layer formed in the second step, the impurities may not be completely removed by the active species such as the NHx*. As a result, the impurities such as chlorine about several atomic % may remain. In the present step, the impurities which are not completely removed by the active species such as the NHx* and remain in the SiN layer can be removed by another active species such as the N*, the N2*, the Ar* and the He* different from the active species such as the NHx*.

When removing the impurities, it is preferable that the inner pressure of the process chamber 201 in the present step (that is, the third step) is set to be lower than the inner pressure of the process chamber 201 in the second step. Further, it is preferable that the inner pressure of the process chamber 201 in the third step is set to be lower than the inner pressure of the process chamber 201 in the second step, and that the inner pressure of the process chamber 201 in the second step is set to be lower than the inner pressure of the process chamber 201 in the first step. By adjusting a pressure balance between each step as described above, it is possible to optimize a lifetime of the active species such as the NHx* generated in the second step, and it is also possible to optimize a lifetime of the active species such as the Nx*, the Ar* and the He* generated in the third step. In particular, it is possible to lengthen the lifetime of the active species such as the Nx*, the Ar* and the He* generated in the third step. In addition, in order to adjust the pressure balance between each step as described above, it is preferable that the supply flow rate of the inert gas supplied in the third step is set to be less than the supply flow rate of the N- and H-containing gas supplied in the second step. That is, by controlling (adjusting) a balance of the supply flow rate of each gas supplied in each step, it is possible to adjust the pressure balance between each step, and it is also possible to optimize the lifetime of each active species generated in each step.

For example, in the present step, it is preferable to reduce the inner pressure of the process chamber 201 to 2 Pa or more and 6 Pa or less, preferably 2.66 Pa or more and 5.32 Pa or less, and more preferably 3 Pa or more and 4 Pa or less. In such a case, it is preferable that the process pressure in the present step is set to be lower than each of the process pressure in the first step and the process pressure in the second step. For example, by setting the flow rate of the inert gas supplied in the present step to be lower than the flow rate of the inert gas supplied in the purge and the flow rate of the N- and H-containing gas supplied in the second step, it is possible to promote a reduction in the process pressure described above. In FIG. 5 is shown an example in which the reduction in the process pressure can be promoted by setting the flow rate of the inert gas supplied in the present step to be lower than the flow rate of the inert gas supplied in the purge and the flow rate of the N- and H-containing gas supplied in the second step.

In the present step, in a case where the inner pressure of the process chamber 201 is set to less than 2 Pa, a generation amount of ions such as N2+, Ar+ and He+ generated together with the active species when the inert gas is excited into the plasma state may rapidly increase. Thereby, an ion attack to the wafer 200 may occur excessively. As a result, a wet etching rate (hereinafter, also referred to as a “WER”) of the SiN film (which is finally formed) may increase, and a wet etching resistance of the SiN film (which is finally formed) may decrease. It is considered that, since a surface layer of the SiN layer is attacked by the ions, a density of the surface layer of the SiN layer is lowered and a density of the SiN film (which is finally formed) is also lowered.

The ion attack described above may occur excessively particularly at the outer periphery of the wafer 200. Thereby, the WER of the SiN film (which is finally formed) tends to increase at the outer periphery of the wafer 200, and the wet etching resistance of the SiN film (which is finally formed) tends to decrease at the outer periphery of the wafer 200. That is, the ion attack may deteriorate a WER uniformity of the SiN film (which is finally formed) on the surface of the wafer 200, that is, a wet etching resistance uniformity of the SiN film (which is finally formed) on the surface of the wafer 200. In addition, the ion attack may destroy a structure of the SiN film at the outer periphery of the wafer 200, and a portion of the SiN film destructed as described above may change to a sparse film. As a result, a thickness of the SiN film (which is finally formed) tends to be thicker at the outer periphery of the wafer 200. That is, the ion attack may deteriorate a thickness uniformity of the SiN film (which is finally formed) on the surface of the wafer 200.

On the other hand, in the present step, by setting the inner pressure of the process chamber 201 to 2 Pa or more, it is possible to reduce the generation amount of the ions such as N2+, Ar+ and He+ generated together with the active species when the inert gas is excited into the plasma state, and it is also possible to suppress an occurrence of the ion attack to the wafer 200. As a result, it is possible to avoid an increase in the WER of the SiN film (which is finally formed), and it is also possible to avoid a decrease in the wet etching resistance of the SiN film (which is finally formed). It is considered that, since the ion attack on the surface layer of the SiN layer can be suppressed although the ions are generated, it is possible to suppress a decrease in the density of the surface layer of the SiN layer and it is also possible to suppress a decrease in the density of the SiN film (which is finally formed).

Further, by suppressing the ion attack, the WER of the SiN film (which is finally formed) increases at the outer periphery of the wafer 200. Thereby, it is possible to eliminate a tendency that the wet etching resistance of the film (which is finally formed) decreases at the outer periphery of the wafer 200. That is, by suppressing the ion attack, it is possible to suppress a deterioration of the WER uniformity of the SiN film (which is finally formed) on the surface of the wafer 200, that is, a deterioration of the wet etching resistance uniformity of the SiN film (which is finally formed) on the surface of the wafer 200. In addition, by suppressing the ion attack, it is also possible to suppress a tendency that the thickness of the SiN film (which is finally formed) becomes thicker at the outer periphery of the wafer 200. That is, by suppressing the ion attack, it is possible to suppress a deterioration of the thickness uniformity of the SiN film (which is finally formed) on the surface of the wafer 200.

In the present step, for example, by setting the inner pressure of the process chamber 201 to 2.66 Pa or more, it is possible to further enhance an effect of suppressing the ion attack, and as a result, it is also possible to more sufficiently obtain the effects described above. Further, in the step, for example, by setting the inner pressure of the process chamber 201 to 3 Pa or more, it is possible to further enhance the effect of suppressing the ion attack, and as a result, it is also possible to more sufficiently obtain the effects described above.

In the present step, in a case where the inner pressure of the process chamber 201 is set to a pressure higher than 6 Pa, the lifetime of the active species such as the Nx*, the Ar* and the He* generated when the inert gas is excited into the plasma state may be shortened. Thereby, it may be difficult for the active species to reach a central portion of the wafer 200. In other words, the active species such as the Nx*, the Ar* and the He* generated when the inert gas is excited into the plasma state may be more likely to be deactivated before reaching the central portion of the wafer 200. Thereby, the WER of the SiN film (which is finally formed) is high at the central portion of the wafer 200, and as a result, the wet etching resistance of the SiN film (which is finally formed) may be lowered at the central portion of the wafer 200. That is, the WER uniformity of the SiN film (which is finally formed) on the surface of the wafer 200 (that is, the wet etching resistance uniformity of the SiN film (which is finally formed) on the surface of the wafer 200) may deteriorate. In addition, since the active species such as the Nx*, the Ar* and the He* are more likely to be deactivated before reaching the central portion of the wafer 200, an effect of densifying the film at the central portion of the wafer 200 may become insufficient, and the thickness of the SiN film (which is finally formed) may become thick at the central portion of the wafer 200. That is, the thickness uniformity of the SiN film (which is finally formed) on the surface of the wafer 200 may deteriorate. It is considered that, since an effect of modifying the SiN layer at the central portion (where the active species cannot easily reach) of the wafer 200 is insufficient while the effect of modifying the SiN layer at the outer periphery (where the active species may easily reach) of the wafer 200 is sufficient, the effect of modifying the SiN layer may differ between the outer periphery and the central portion of the wafer 200.

On the other hand, in the present step, by setting the inner pressure of the process chamber 201 to 6 Pa or less, it is possible to lengthen the lifetime of the active species such as the Nx*, the Ar* and the He* generated when the inert gas is excited into the plasma state, and it is also possible for the active species such as the Nx*, the Ar* and the He* to sufficiently reach the central portion of the wafer 200. As a result, it is possible to avoid the increase in the WER of the SiN film (which is finally formed) at the central portion of the wafer 200, and it is also possible to avoid the decrease in the wet etching resistance of the SiN film (which is finally formed) at the central portion of the wafer 200. That is, it is possible to suppress the deterioration of the WER uniformity of the SiN film (which is finally formed) on the surface of the wafer 200, that is, the deterioration of the wet etching resistance uniformity of the SiN film (which is finally formed) on the surface of the wafer 200. In addition, since the active the active species such as the Nx*, the Ar* and the He* can sufficiently reach the central portion of the wafer 200, it is also possible to avoid a tendency that the thickness of the SiN film (which is finally formed) becomes thicker at the central portion of the wafer 200. That is, it is possible to suppress the deterioration of the thickness uniformity of the SiN film (which is finally formed) on the surface of the wafer 200. It is considered that this is because not only the effect of modifying the SiN layer at the outer periphery of the wafer 200 can be sufficiently obtained, but also the effect of modifying the SiN layer at the central portion of the wafer 200 can be sufficiently obtained. Further, it is considered that this is because not only the effect of densifying the SiN layer at the outer periphery of the wafer 200 can be sufficiently obtained, but also the effect of densifying the SiN layer at the central portion of the wafer 200 can be sufficiently obtained.

For example, in the present step, by setting the inner pressure of the process chamber 201 to 5.32 Pa or less, it is possible to further enhance an effect of lengthening the lifetime of the active species such as the Nx*, the Ar* and the He*, and it is also possible to further obtain the effects described above (for example, the effect of modifying the SiN layer and the effect of densifying the SiN layer). Further, in the present step, by setting the inner pressure of the lifetime of the active species such as the Nx*, the Ar* and the He*, and it is also possible to further obtain the effects described above.

From the above, in the present step, it is preferable to set the inner pressure of the process chamber 201 to 2 Pa or more and 6 Pa or less, preferably 2.66 Pa or more and 5.32 Pa or less, and more preferably 3 Pa or more and 4 Pa or less.

For example, it is preferable that the supply time (time duration) of supplying the plasma-excited inert gas by exciting the inert gas into the plasma state in the present step (that is, the third step) is set to be longer than the supply time (time duration) of supplying the plasma-excited N- and H-containing gas by exciting the N- and H-containing gas into the plasma state in the second step. In addition, it is preferable that the supply time (time duration) of supplying the plasma-excited inert gas by exciting the inert gas into the plasma state in the present step (that is, the third step) is set to be longer than the supply time (time duration) of supplying the source gas in the first step. In addition, it is preferable that the supply time (time duration) of supplying the plasma-excited inert gas by exciting the inert gas into the plasma state in the present step (that is, the third step) is set to be longer than the supply time (time duration) of supplying the plasma-excited N- and H-containing gas by exciting the N- and H-containing gas into the plasma state in the second step, and the supply time (time duration) of supplying the plasma-excited N- and H-containing gas by exciting the N- and H-containing gas into the plasma state in the second step is set to be longer than the supply time (time duration) of supplying the source gas in the first step. By adjusting a balance of an exposure time (time duration) of the gas or the active species to the wafer 200 (hereinafter, also referred to as an “exposure time of the gas and the like” or an “exposure time of the active species”) between each step as described above, it is possible to optimize the modifying reaction by the active species such as NHx* in the second step, and it is also possible to optimize the modifying reaction by the active species such as the Nx*, the Ar* and the He* in the third step. In particular, it is possible to optimize the modifying reaction by the active species such as the Nx*, the Ar* and the He* in the third step.

After the SiN layer is modified, the application of the RF power to the electrode 300 is stopped, and a supply of the plasma-excited inert gas to the wafer 200 is stopped. In a case where the cycle described above is repeatedly performed a plurality of times, the first step is performed again after the third step is completed. However, the inner atmosphere of the process chamber 201 may be purged in the non-plasma atmosphere before the first step is performed again. In such a case, a substance such as a residual gas remaining in the process chamber 201 is removed from the process chamber 201 according to the same sequence as those of the first step. As a result, it is possible to suppress phenomena such as a mixture of the plasma-excited inert gas remaining in the process chamber 201 and the source gas supplied into the process chamber 201 in the first step, an unintended reaction due to the mixture (for example, a gas phase reaction and a plasma gas phase reaction) and the generation of the particles.

As the inert gas, for example, nitrogen (N2) gas and a rare gas such as argon (Ar) gas, helium (He) gas, neon (Ne) gas, xenon (Xe) gas, krypton (Kr) gas and radon (Rn) gas may be used. For example, one or more of the gases exemplified above as the inert gas may be used as the inert gas.

### <Performing Cycle Predetermined Number of Times>

By performing the cycle wherein the first step, the second step and the third step described above are performed non-simultaneously (that is, in a non-synchronized manner) in this order a predetermined number of times (n times, wherein n is an integer equal to or greater than 1), it is possible to form the silicon nitride film (SiN film) of a predetermined thickness (which serves as the film of a predetermined thickness) on the surface of the base (that is, on the surface of the wafer 200). It is preferable that the cycle described above is repeatedly performed a plurality of times. That is, it is preferable that the cycle is repeatedly performed a plurality of times until a thickness of a stacked film (that is, the SiN film) reaches a desired thickness while a thickness of the SiN layer formed per each cycle is smaller than the desired thickness. In addition, in a case where the gas containing nitrogen, carbon and hydrogen is used as the reactive gas, for example, a silicon carbonitride layer (SiCN layer) can be formed in the second step, and by performing the cycle described above a predetermined number of times, it is possible to form a silicon carbonitride film (SiCN film) serving as the film on the surface of the wafer 200.

### <After-Purge Step and Returning to Atmospheric Pressure Step>

After a process of forming the SiN film of a desired thickness on the wafer 200 is completed, the inert gas serving as the purge gas is supplied into the process chamber 201 through each of the nozzles 249a, 249b and 249c, and then is exhausted through the exhaust port 231a. Thereby, the inner atmosphere of the process chamber 201 is purged with the purge gas. As a result, a substance such as a residual gas remaining in the process chamber 201 and reaction by-products remaining in the process chamber 201 are removed from the process chamber 201 (after-purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

### <Boat Unloading Step and Wafer Discharging Step>

Thereafter, the seal cap 219 is lowered by the boat elevator 115 and the lower end of the manifold 209 is opened. Then, the boat 217 with the processed wafers 200 supported therein is unloaded (transferred) out of the reaction tube 203 through the lower end of the manifold 209 (boat unloading step). After the boat 217 is unloaded, the shutter 219s is moved such that the lower end opening of the manifold 209 is sealed by the shutter 219s through the O-ring 220c (shutter closing step).

### <Wafer Cooling Step>

After the boat unloading step, that is, after the shutter closing step, the processed wafers 200 are cooled down to a predetermined temperature at which the processed wafers 200 can be discharged (taken out) while being supported by the boat 217 (wafer cooling step).

### <Wafer Discharging Step>

After the wafer cooling step, the processed wafers 200 cooled down to the predetermined temperature at which the processed wafers 200 can be discharged are discharged (transferred) from the boat 217 (wafer discharging step).

In a manner described above, a series of processes (that is, the substrate processing) of forming the film on the wafer 200 is completed. The substrate processing may be performed a predetermined number of times.

The present embodiments are described by way of an example in which the film-forming step is performed in the process chamber 201 while the wafers 200 are supported by the boat 217 in the process chamber 201. In such a case, as shown in FIG. 7A, the interval (arrangement pitch) of the wafers 200 when the film-forming step is performed may be set to a reference interval (reference arrangement pitch) that enables the boat 217 to accommodate the maximum number of wafers supportable by the boat 217. The interval (arrangement pitch) of the wafers 200 refers to an interval (distance) between adjacent wafers among the wafers 200. For example, when 100 wafers can be maximally supported by the boat 217, the film-forming step may be performed in a state where 100 wafers serving as the wafers 200 are supported by the support structures 217b of the boat 217, respectively. Further, the interval (arrangement pitch) of the wafers 200 in FIG. 7A (that is, an interval or arrangement pitch between adjacent support structures among the support structures 217b capable of supporting the wafers 200) can be set to 6 mm to 12 mm, for example.

Alternatively, for example, as shown in FIG. 7B or 7C, the interval (arrangement pitch) of the wafers 200 when the film-forming step is performed may be set to be greater than the reference interval (reference arrangement pitch) that enables the boat 217 to accommodate the maximum number of wafers supportable by the boat 217. As a result, it is possible to suppress a deactivation of the active species caused by the active species colliding with the wafers 200 when the active species flow between adjacent wafers among the wafers 200, and it is also possible to improve a probability that the active species reach the central portion of the wafer 200. Further, as a result, it is possible to suppress the increase in the WER of the SiN film (which is finally formed) at the central portion of the wafer 200, and it is also possible to suppress the decrease in the wet etching resistance of the SiN film (which is finally formed) at the central portion of the wafer 200. That is, it is possible to suppress the deterioration of the WER uniformity of the SiN film (which is finally formed) on the surface of the wafer 200, that is, the deterioration of the wet etching resistance uniformity of the SiN film (which is finally formed) on the surface of the wafer 200. In addition, it is also possible to suppress the tendency that the thickness of the SiN film (which is finally formed) becomes thicker at the central portion of the wafer 200. That is, it is possible to suppress the deterioration of the thickness uniformity of the SiN film (which is finally formed) on the surface of the wafer 200. In particular, among the active species such as such as the Nx*, the Ar* and the He*, the lifetime of the active species such as the Nx is relatively short and the active species such as the Nx easily deactivated. As a result, the effects described above are particularly remarkable in the third step.

In such a case, for example, as shown in FIG. 7B, the interval (arrangement pitch) of the wafers 200 when the film-forming step is performed may be set to be twice or more the reference interval (reference arrangement pitch) that enables the boat 217 to accommodate the maximum number of wafers supportable by the boat 217. For example, when 120 wafers can be maximally supported by the boat 217, the film-forming step may be performed in a state where 60 wafers serving as the wafers 200 are supported by the support structures 217b of the boat 217, respectively, such that the interval (arrangement pitch) between adjacent wafers among the wafers 200 is twice the reference interval. Further, the interval (arrangement pitch) of the wafers 200 in FIG. 7B can be set to 12 mm to 24 mm or more, for example. As a result, it is possible to further suppress the deactivation of the active species caused by the active species colliding with the wafers 200, and it is also possible to further improve the probability that the active species reach the central portion of the wafer 200. Further, as a result, it is possible to sufficiently suppress the increase in the WER of the SiN film (which is finally formed) at the central portion of the wafer 200, and it is also possible to sufficiently suppress the decrease in the wet etching resistance of the SiN film (which is finally formed) at the central portion of the wafer 200. That is, it is possible to sufficiently suppress the deterioration of the WER uniformity of the SiN film (which is finally formed) on the surface of the wafer 200, that is, the deterioration of the wet etching resistance uniformity of the SiN film (which is finally formed) on the surface of the wafer 200. In addition, it is also possible to sufficiently suppress the tendency that the thickness of the SiN film (which is finally formed) becomes thicker at the central portion of the wafer 200. That is, it is possible to sufficiently suppress the deterioration of the thickness uniformity of the SiN film (which is finally formed) on the surface of the wafer 200. In particular, among the active species such as such as the Nx*, the Ar* and the He*, the lifetime of the active species such as the Nx is relatively short and the active species such as the Nx easily deactivated. As a result, the effects described above are particularly remarkable in the third step.

In such a case, for example, the interval (arrangement pitch) of the wafers 200 when the film-forming step is performed may be set to be three times or more the reference interval (reference arrangement pitch) that enables the boat 217 to accommodate the maximum number of wafers supportable by the boat 217. For example, when 120 wafers can be maximally supported by the boat 217, the film-forming step may be performed in a state where 40 wafers serving as the wafers 200 are supported by the support structures 217b of the boat 217, respectively, such that the interval (arrangement pitch) between adjacent wafers among the wafers 200 is three times the reference interval. Further, the interval (arrangement pitch) of the wafers 200 can be set to 18 mm to 36 mm or more, for example. As a result, it is possible to further suppress the deactivation of the active species caused by the active species colliding with the wafers 200, and it is also possible to further improve the probability that the active species reach the central portion of the wafer 200. Further, as a result, it is possible to sufficiently suppress the increase in the WER of the SiN film (which is finally formed) at the central portion of the wafer 200, and it is also possible to sufficiently suppress the decrease in the wet etching resistance of the SiN film (which is finally formed) at the central portion of the wafer 200. That is, it is possible to sufficiently suppress the deterioration of the WER uniformity of the SiN film (which is finally formed) on the surface of the wafer 200, that is, the deterioration of the wet etching resistance uniformity of the SiN film (which is finally formed) on the surface of the wafer 200. In addition, it is also possible to sufficiently suppress the tendency that the thickness of the SiN film (which is finally formed) becomes thicker at the central portion of the wafer 200. That is, it is possible to sufficiently suppress the deterioration of the thickness uniformity of the SiN film (which is finally formed) on the surface of the wafer 200. In particular, among the active species such as such as the Nx*, the Ar* and the He*, the lifetime of the active species such as the Nx is relatively short and the active species such as the Nx easily deactivated. As a result, the effects described above are particularly remarkable in the third step.

In such a case, for example, as shown in FIG. 7C, the interval (arrangement pitch) of the wafers 200 when the film-forming step is performed may be set to be four times or more the reference interval (reference arrangement pitch) that enables the boat 217 to accommodate the maximum number of wafers supportable by the boat 217. For example, when 120 wafers can be maximally supported by the boat 217, the film-forming step may be performed in a state where 30 wafers serving as the wafers 200 are supported by the support structures 217b of the boat 217, respectively, such that the interval (arrangement pitch) between adjacent wafers among the wafers 200 is four times the reference interval. Further, the interval (arrangement pitch) of the wafers 200 in FIG. 7C can be set to 24 mm to 48 mm or more, for example. As a result, it is possible to further suppress the deactivation of the active species caused by the active species colliding with the wafers 200, and it is also possible to further improve the probability that the active species reach the central portion of the wafer 200. Further, as a result, it is possible to further sufficiently suppress the increase in the WER of the SiN film (which is finally formed) at the central portion of the wafer 200, and it is also possible to further sufficiently suppress the decrease in the wet etching resistance of the SiN film (which is finally formed) at the central portion of the wafer 200. That is, it is possible to further sufficiently suppress the deterioration of the WER uniformity of the SiN film (which is finally formed) on the surface of the wafer 200, that is, the deterioration of the wet etching resistance uniformity of the SiN film (which is finally formed) on the surface of the wafer 200. In addition, it is also possible to further sufficiently suppress the tendency that the thickness of the SiN film (which is finally formed) becomes thicker at the central portion of the wafer 200. That is, it is possible to further sufficiently suppress the deterioration of the thickness uniformity of the SiN film (which is finally formed) on the surface of the wafer 200. In particular, among the active species such as such as the Nx*, the Ar* and the He*, the lifetime of the active species such as the Nx is relatively short and the active species such as the Nx easily deactivated. As a result, the effects described above are particularly remarkable in the third step.

However, when the interval (arrangement pitch) between adjacent wafers among the wafers 200 is too large, the number of the wafers 200 that can be processed simultaneously in the film-forming step may decrease. Thereby, a productivity may be lowered. Considering that the productivity is at a practical level, it is preferable that the interval (arrangement pitch) between adjacent wafers among the wafers 200 is set to be five times or less the reference interval (reference arrangement pitch) that enables the boat 217 to accommodate the maximum number of wafers supportable by the boat 217. In such a case, the interval (arrangement pitch) of the wafers 200 can be set to 30 mm to 60 mm or less, for example.

As described above, in order to improve the probability that the active species reach the central portion of the wafer 200 and to obtain the productivity at the practical level, it is preferable that the interval (arrangement pitch) between adjacent wafers among the wafers 200 is set to 12 mm or more and 60 mm or less, for example.

For example, in order to further improve the probability that the active species reach the central portion of the wafer 200 while obtaining the productivity at the practical level, it is preferable that the interval (arrangement pitch) between adjacent wafers among the wafers 200 is set to 15 mm or more and 60 mm or less, for example. For example, in order to more further improve the probability that the active species reach the central portion of the wafer 200 while obtaining the productivity at the practical level, the interval (arrangement pitch) between adjacent wafers among the wafers 200 is preferably set to 18 mm or more and 60 mm or less, for example, more preferably, set to 24 mm or more and 60 mm or less, more further preferably, set to 36 mm or more and 60 mm or less, and even more further preferably, set to 48 mm or more and 60 mm or less. Each interval (arrangement pitch) exemplified above may also be regarded as NXR an arrangement pitch between adjacent wafers among the wafers 200 emphasizing the probability of the active species reaching the central portion of the wafer 200.

For example, in order to further improve the productivity while improving the probability that the active species reach the central portion of the wafer 200, the interval (arrangement pitch) between adjacent wafers among the wafers 200 is preferably set to 12 mm or more and 48 mm or less, for example, more preferably, set to 12 mm or more and 40 mm or less, more further preferably, set to 12 mm or more and 36 mm or less, and even more further preferably, set to 12 mm or more and 30 mm or less. Each interval (arrangement pitch) exemplified above may also be regarded as an arrangement pitch between adjacent wafers among the wafers 200 emphasizing the productivity.

For examples, upper limits and lower limits of numerical ranges exemplified above as the interval (arrangement pitch) between adjacent wafers among the wafers 200 may be appropriately combined in consideration of a balance between the probability of the active species reaching the central portion of the wafer 200 and the productivity. Further, in such a case, the present embodiments are not limited to an example in which the wafers 200 are supported by the boat 217 where the interval (arrangement pitch) between adjacent support structures among the support structures 217b is set to 6 mm to 12 mm, for example. That is, the present embodiments may also be applied to a case where the wafers 200 are supported by the boat 217 where the interval (arrangement pitch) between adjacent support structures among the support structures 217b itself is set to be within the numerical ranges exemplified above.

### (3) EFFECTS ACCORDING TO PRESENT EMBODIMENTS

According to the present embodiments, it is possible to obtain one or more of the following effects.

(a) By adjusting the pressure balance between each step such that the inner pressure of the process chamber 201 in the third step is set to be lower than the inner pressure of the process chamber 201 in the second step, it is possible to optimize the lifetime of the active species such as the Nx*, the Ar* and the He* (which are easily deactivated and whose lifetime is relatively short) generated in the third step. Thereby, it is possible to enhance the effect of modifying the SiN layer in the third step. As a result, it is possible to lower the WER of the SiN film (which is finally formed), and it is also possible to improve the wet etching resistance of the SiN film (which is finally formed). Further, it is possible to densify the SiN film (which is finally formed), and it is also possible to form the SiN film whose density is high. That is, it is possible to improve a quality of the SiN film (which is finally formed), and it is also possible to form a high quality SiN film. Further, in order to adjust the pressure balance between each step as described above, it is preferable that the supply flow rate of the inert gas supplied in the third step is set to be less than the supply flow rate of the N- and H-containing gas supplied in the second step.

For example, it is preferable that the pressure balance between each step is adjusted such that the inner pressure of the process chamber 201 in the third step is set to be lower than the inner pressure of the process chamber 201 in the second step and that the inner pressure of the process chamber 201 in the second step is set to be lower than the inner pressure of the process chamber 201 in the first step. Thereby, it is possible to optimize the lifetime of the active species such as the NHx* generated in the second step, and it is also possible to optimize the lifetime of the active species such as the Nx*, the Ar* and the He* (which are easily deactivated and whose lifetime is relatively short) generated in the third step. In particular, it is possible to further lengthen the lifetime of the active species such as the Nx*, the Ar* and the He* generated in the third step. Thereby, it is possible to enhance the effect of modifying the SiN layer in the third step. As a result, it is possible to lower the WER of the SiN film (which is finally formed), and it is also possible to improve the wet etching resistance of the SiN film (which is finally formed). That is, it is possible to improve the quality of the SiN film (which is finally formed), and it is also possible to form the high quality SiN film.

(b) By setting the inner pressure of the process chamber 201 in the third step to 2 Pa or more, preferably, 2.66 Pa or more, and more preferably, 3 Pa or more, it is possible to reduce the generation amount of the ions such as the N2+, the Ar+ and the He+ generated together with the active species when the inert gas is excited into the plasma state, and it is also possible to suppress the ion attack to the wafer 200. As a result, it is possible to avoid the increase in the WER of the SiN film (which is finally formed), and it is also possible to avoid the decrease in the wet etching resistance of the SiN film (which is finally formed). Further, by suppressing the ion attack, the WER of the SiN film (which is finally formed) increases at the outer periphery of the wafer 200. Thereby, it is possible to eliminate a tendency that the WER of the SiN film (which is finally formed) increases at the outer periphery of the wafer 200, and it is also possible to eliminate the tendency that the wet etching resistance of the film (which is finally formed) decreases at the outer periphery of the wafer 200. That is, it is possible to suppress the deterioration of the WER uniformity of the SiN film (which is finally formed) on the surface of the wafer 200, that is, the deterioration of the wet etching resistance uniformity of the SiN film (which is finally formed) on the surface of the wafer 200. In addition, by suppressing the ion attack, it is also possible to eliminate the tendency that the thickness of the SiN film (which is finally formed) becomes thicker at the outer periphery of the wafer 200. That is, by suppressing the ion attack, it is possible to suppress the deterioration of the thickness uniformity of the SiN film (which is finally formed) on the surface of the wafer 200.

(c) By setting the inner pressure of the process chamber 201 in the third step to 6 Pa or less, preferably, 5.32 Pa or less, and more preferably, 4 Pa or less, it is possible to lengthen the lifetime of the active species such as the Nx*, the Ar* and the He* generated when the inert gas is excited into the plasma state, and it is also possible for the active species such as the Nx*, the Ar* and the He* to sufficiently reach the central portion of the wafer 200. As a result, it is possible to avoid the increase in the WER of the SiN film (which is finally formed) at the central portion of the wafer 200, and it is also possible to avoid the decrease in the wet etching resistance of the SiN film (which is finally formed) at the central portion of the wafer 200. That is, it is possible to suppress the deterioration of the WER uniformity of the SiN film (which is finally formed) on the surface of the wafer 200, that is, the deterioration of the wet etching resistance uniformity of the SiN film (which is finally formed) on the surface of the wafer 200. In addition, since the active the active species such as the Nx*, the Ar* and the He* can sufficiently reach the central portion of the wafer 200, it is also possible to avoid the tendency that the thickness of the SiN film (which is finally formed) becomes thicker at the central portion of the wafer 200. That is, it is possible to suppress the deterioration of the thickness uniformity of the SiN film (which is finally formed) on the surface of the wafer 200.

(d) By adjusting the balance of the exposure time of the active species to the wafer 200 between each step such that the supply time (time duration) of supplying the plasma-excited inert gas by exciting the inert gas into the plasma state in the third step is set to be longer than the supply time (time duration) of supplying the plasma-excited N- and H-containing gas by exciting the N- and H-containing gas into the plasma state in the second step, it is possible to optimize the modifying reaction by the active species such as the Nx*, the Ar* and the He* in the third step. That is, it is possible to more appropriately generate the modifying reaction described above. On the other hand, in a case where the supply time (time duration) of supplying the plasma-excited inert gas by exciting the inert gas into the plasma state in the third step is set to be shorter than the supply time (time duration) of supplying the plasma-excited N- and H-containing gas by exciting the N- and H-containing gas into the plasma state in the second step, the modifying reaction by the active species such as the Nx*, the Ar* and the He* may be insufficient.

For example, it is preferable to adjust the balance of the exposure time of the gas and the like to the wafer 200 between each step such that the supply time (time duration) of supplying the plasma-excited inert gas by exciting the inert gas into the plasma state in the third step is set to be longer than the supply time (time duration) of supplying the source gas in the first step. As a result, it is possible to optimize the modifying reaction by the active species such as the Nx*, the Ar* and the He* in the third step. That is, it is possible to more appropriately generate the modifying reaction described above. On the other hand, in a case where the supply time (time duration) of supplying the plasma-excited inert gas by exciting the inert gas into the plasma state in the third step is set to be shorter than the supply time (time duration) of supplying the source gas in the first step, the modifying reaction by the active species such as the Nx*, the Ar* and the He* may be insufficient.

Further, it is preferable to adjust the balance of the exposure time of the gas and the like to the wafer 200 between each step such that the supply time (time duration) of supplying the plasma-excited inert gas by exciting the inert gas into the plasma state in the third step is set to be longer than the supply time (time duration) of supplying the plasma-excited N- and H-containing gas by exciting the N- and H-containing gas into the plasma state in the second step and such that the supply time (time duration) of supplying the plasma-excited N- and H-containing gas by exciting the N- and H-containing gas into the plasma state in the second step is set to be longer than the supply time (time duration) of supplying the source gas in the first step. As a result, it is possible to optimize the modifying reaction by the active species such as NHx* in the second step, and it is also possible to optimize the modifying reaction by the active species such as the Nx*, the Ar* and the He* in the third step. In particular, it is possible to optimize the modifying reaction by the active species such as the Nx*, the Ar* and the He* in the third step. That is, it is possible to more appropriately generate the modifying reaction described above.

(e) By applying the power to the electrode 300 provided outside the process vessel in the third step such that the inert gas is excited into the plasma state inside the process vessel, it is possible to prevent an occurrence of an abnormal discharge. As a result, it is possible to suppress the damage (plasma damage) to the components in the process vessel or the damage to the wafer 200, and it is also possible to suppress the generation of the particles.

In addition, for example, in a case where an electrode for generating the plasma is provided in a plasma generation chamber communicating with an inside of the process vessel and the inert gas is ejected into the process vessel by exciting the inert gas into the plasma state in the plasma generation chamber under the Pressure condition as described above, the abnormal discharge may occur. That is, in such a case, a local discharge that is difficult to control may occur randomly in the vicinity of an ejection port through which the active species generated in the plasma generation chamber is ejected from the plasma generation chamber into the process vessel. When such an abnormal discharge occurs in the plasma generation chamber, the damage may occur to components such as an inner wall of a partition constituting the plasma generation chamber and the nozzles provided in the plasma generation chamber. Further, when such an abnormal discharge occurs outside the plasma generation chamber, that is, inside the process vessel, the components in the process vessel and the wafer 200 may be damaged. In both cases, the particles may also be induced. In addition, as the process pressure is lowered, a mean free path of the active species may be longer, an amount of a charge build-up on an inner wall of the ejection port may be greater, and an electric field extending from there to an outside of the ejection port may become stronger. As a result, a sufficient kinetic energy to generate the abnormal discharge may be imparted to plasma electrons through the electric field acceleration. That is, the lower the process pressure, the more likely the abnormal discharge occurs.

On the other hand, by applying the power to the electrode 300 provided outside the process vessel such that the inert gas is excited into the plasma state inside the process vessel, it is possible to prevent the occurrence of the abnormal discharge described above. As a result, it is possible to suppress the damage (plasma damage) to the components in the process vessel or the damage to the wafer 200, and it is also possible to suppress the generation of the particles. The effects described above are particularly remarkable as the process pressure is lowered.

Further, by applying the power to the electrode 300 provided outside the process vessel in the second step such that the N- and H-containing gas is excited into the plasma state inside the process vessel, it is possible to prevent the occurrence of the abnormal discharge. As a result, it is possible to suppress the damage (plasma damage) to the components in the process vessel or the damage to the wafer 200, and it is also possible to suppress the generation of the particles.

(f) By setting the interval (arrangement pitch) of the wafers 200 when the film-forming step is performed to be greater than the reference interval (reference arrangement pitch) that enables the boat 217 to accommodate the maximum number of wafers supportable by the boat 217, it is possible to suppress the deactivation of the active species caused by the active species colliding with the wafers 200. As a result, it is possible to improve the probability that the active species reach the central portion of the wafer 200. Further, as a result, it is possible to suppress the increase in the WER of the SiN film (which is finally formed) at the central portion of the wafer 200, and it is also possible to suppress the decrease in the wet etching resistance of the SiN film (which is finally formed) at the central portion of the wafer 200. That is, it is possible to suppress the deterioration of the WER uniformity of the SiN film (which is finally formed) on the surface of the wafer 200, that is, the deterioration of the wet etching resistance uniformity of the SiN film (which is finally formed) on the surface of the wafer 200. In addition, it is also possible to suppress the tendency that the thickness of the SiN film (which is finally formed) becomes thicker at the central portion of the wafer 200. That is, it is possible to suppress the deterioration of the thickness uniformity of the SiN film (which is finally formed) on the surface of the wafer 200. In particular, among the active species such as such as the Nx*, the Ar* and the He*, the lifetime of the active species such as the Nx is relatively short and the active species such as the Nx easily deactivated. As a result, the effects described above are particularly remarkable in the third step. That is, the effects described above are particularly remarkable in a case where, among the inert gas such as the N2 gas, the argon (Ar) gas and the helium (He) gas, the N2 gas is used as the inert gas and is supplied to the wafer 200 by exciting the N2 gas into the plasma state.

For example, the interval (arrangement pitch) of the wafers 200 when the film-forming step is performed may be set to be twice or more the reference interval (reference arrangement pitch) that enables the boat 217 to accommodate the maximum number of wafers supportable by the boat 217. In such a case, the interval (arrangement pitch) of the wafers 200 can be set to 12 mm to 24 mm or more, for example. Thereby, it is possible to further suppress the deactivation of the active species caused by the active species colliding with the wafers 200, and it is also possible to further improve the probability that the active species reach the central portion of the wafer 200. As a result, it is possible to sufficiently obtain the effects described above.

For example, the interval (arrangement pitch) of the wafers 200 when the film-forming step is performed may be set to be three times or more the reference interval (reference arrangement pitch) that enables the boat 217 to accommodate the maximum number of wafers supportable by the boat 217. In such a case, the interval (arrangement pitch) of the wafers 200 can be set to 18 mm to 36 mm or more, for example. Thereby, it is possible to further suppress the deactivation of the active species caused by the active species colliding with the wafers 200, and it is also possible to further improve the probability that the active species reach the central portion of the wafer 200. As a result, it is possible to more sufficiently obtain the effects described above.

For example, the interval (arrangement pitch) of the wafers 200 when the film-forming step is performed may be set to be four times or more the reference interval (reference arrangement pitch) that enables the boat 217 to accommodate the maximum number of wafers supportable by the boat 217. In such a case, the interval (arrangement pitch) of the wafers 200 can be set to 24 mm to 48 mm or more, for example. Thereby, it is possible to further suppress the deactivation of the active species caused by the active species colliding with the wafers 200, and it is also possible to further improve the probability that the active species reach the central portion of the wafer 200. As a result, it is possible to more sufficiently obtain the effects described above.

(g) The effects described above are particularly remarkable in a case where, in the third step, the plasma-excited inert gas is supplied to the wafer 200 through the edge (side portion) of the wafer 200 by exciting the inert gas into the plasma state. For example, the effects described above are particularly remarkable in a case where, in the second step, the plasma-excited N- and H-containing gas is supplied to the wafer 200 through the edge (side portion) of the wafer 200 by exciting the N- and H-containing gas into the plasma state. For example, the effects described above are particularly remarkable in a case where, in the first step, the source gas is supplied to the wafer 200 through the edge (side portion) of the wafer 200. However, the present embodiments are not limited to the cases where the gases are supplied to the wafer 200 through the edge (side portion) of the wafer 200.

(h) In a case where the film is formed at a low temperature using the plasma, the wet etching resistance of the film may be lowered. Thereby, the quality of the film may deteriorate. However, according to the present embodiments, even when the film is formed at the low temperature using the plasma, it is possible to obtain the effects described above, and it is also possible to form a high quality film.

### (4) MODIFIED EXAMPLES

The process sequence according to the embodiments described above may be modified as shown in the following modified examples. The modified examples may be appropriately combined. In addition, unless otherwise described, a process sequence and process conditions of each step of each of the modified examples or combinations thereof may be substantially the same as the process sequence and the process conditions of each step of the embodiments described above.

### First Modified Example

By using a gas containing a silicon (Si)-nitrogen (N) bond as the source gas described above, the source gas may act not only as a silicon source but also as a nitrogen source. That is, it is possible to omit the supply of the N- and H-containing gas. That is, in the film-forming step, the SiN film may be formed on the wafer 200 according to a process sequence shown in FIG. 6 and below.

(Source gas→P→Plasma-excited inert gas→P)×n

In such a case, the film is formed on the wafer 200 by performing a cycle a predetermined number of times. The cycle of the first modified example may include: (a) supplying the source gas to the wafer 200 in the process vessel; and (c) supplying the inert gas to the wafer 200 in the process vessel by exciting the inert gas into the plasma state. In the cycle of the first modified example, (a) and (c) are performed non-simultaneously. Further, the process sequence of the first modified example described above is an example in which the cycle of performing (a) and (c) non-simultaneously is performed the predetermined number of times with a step of purging the inner atmosphere of the process vessel performed between (a) and (c).

In such a case, it is preferable to set the inner pressure of the process vessel to 2 Pa or more and 6 Pa or less, preferably 2.66 Pa or more and 5.32 Pa or less, and more preferably 3 Pa or more and 4 Pa or less in (c).

In the present modified example, for example, as the source gas (that is, the gas containing the S—N bond, a silylamine gas such as monosilylamine ((SiH3)NH2, abbreviated as MSA) gas, disilylamine ((SiH3)2NH, abbreviated as DSA) gas, and trisilylamine ((SiH3)3N, abbreviated as TSA) gas may be used. For example, one or more of the gases exemplified above may be used as the source gas. Among the gases exemplified above as the source gas, it is preferable that the TSA containing three S—N bonds is used as the source gas. It is possible to supply the source gas to the wafer 200 through the source gas supplier described above. In the present modified example, the process conditions of supplying the source gas may be substantially the same as those of the first step of the process sequence in the embodiments described above.

In the present modified example, similar to the inert gas in the third step of the process sequence in the embodiments described above, the N2 gas or the rare gas such as the argon (Ar) gas, the helium (He) gas, the neon (Ne) gas and the xenon (Xe) gas may be used as the inert gas. For example, one or more of the gases exemplified above as the inert gas may be used as the inert gas. In the present modified example, among the gases exemplified above as the inert gas, it is preferable that the N2 gas is used as the inert gas. It is possible to supply the inert gas to the wafer 200 through the inert gas supplier described above. In the present modified example, the process conditions of supplying the inert gas may be substantially the same as those of the third step of the process sequence in the embodiments described above.

Even in the present modified example, it is possible to obtain substantially the same effects as in the embodiments described above. Further, according to the present modified example, it is possible to omit the supply of the N- and H-containing gas. Thereby, it is possible to shorten a process time. As a result, it is possible to improve a throughput, that is, the productivity.

### Second Modified Example

The cycle of the embodiments described above may further include a step of supplying an oxygen (O)-containing gas to the wafer 200. In such a case, it is possible to form a silicon oxynitride film (SiON film) on the wafer 200. Further, in such a case, the oxygen-containing gas may be supplied to the wafer 200 without exciting the oxygen-containing gas into a plasma state or may be supplied to the wafer 200 by exciting the oxygen-containing gas into the plasma state. That is, in the film-forming step, it is possible to form the SiON film on the wafer 200 in accordance with one or more of process sequences shown below. For example, similar to the embodiments described above, the purge before and/or after the supply of the inert gas (which is plasma-excited) may be omitted.

(Source gas→P→O-containing gas→P→Plasma-excited N- and H-containing gas→P→Plasma-excited inert gas→P)×n

(Source gas→P→Plasma-excited N- and H-containing gas→P→O-containing gas→P→Plasma-excited inert gas→P)×n

(Source gas→P→Plasma-excited N- and H-containing gas→P→Plasma-excited inert gas→P→0-containing gas→P)×n

(Source gas→P→Plasma-excited O-containing gas→P→Plasma-excited N- and H-containing gas→P→Plasma-excited inert gas→P)×n

(Source gas→P→Plasma-excited N- and H-containing gas→P→Plasma-excited O-containing gas→P→Plasma-excited inert gas→P)×n

(Source gas→P→Plasma-excited N- and H-containing gas→P→Plasma-excited inert gas→P→Plasma-excited O-containing gas→P)×n

In the present modified example, it is possible to supply the oxygen-containing gas to the wafer 200 through the oxygen-containing gas supplier described above. In the present modified example, the process conditions of supplying the oxygen-containing gas may be substantially the same as those of the second step of the process sequence in the embodiments described above. In addition, a hydrogen (H)-containing gas may be supplied together with the oxygen-containing gas. For example, the hydrogen-containing gas may be supplied through the source gas supplier or the N- and H-containing gas supplier.

As the oxygen-containing gas, for example, a gas such as oxygen (O2) gas, ozone (O3) gas, water vapor (H2O) gas, hydrogen peroxide (H2O2) gas, nitrous oxide (N2O) gas, nitrogen monoxide (NO) gas, nitrogen dioxide (NO2) gas, carbon monoxide (CO) gas and carbon dioxide (CO2) gas may be used. For example, one or more of the gases exemplified above as the oxygen-containing gas may be used as the oxygen-containing gas.

In a case where the hydrogen-containing gas is supplied together with the oxygen-containing gas, as the hydrogen-containing gas, for example, a gas such as hydrogen (H2) gas and deuterium (2H2) gas may be used. The deuterium (2H2) gas may also be represented by deuterium (D2) gas. For example, one or more of the gases exemplified above as the hydrogen-containing gas may be used as the hydrogen-containing gas.

Even in the present modified example, it is possible to obtain substantially the same effects as in the embodiments described above. That is, even in the case where the cycle of the embodiments described above further includes the step of supplying the oxygen-containing gas to the wafer 200 and the SiON film is formed on the wafer 200, it is possible to obtain substantially the same effects as in the embodiments described above.

For example, the cycle of the first modified example described above may further include the step of supplying the oxygen-containing gas to the wafer 200. In such a case, it is possible to form a silicon oxynitride film (SiON film) on the wafer 200. Further, in such a case, the oxygen-containing gas may be supplied to the wafer 200 without exciting the oxygen-containing gas into the plasma state or may be supplied to the wafer 200 by exciting the oxygen-containing gas into the plasma state. That is, in the film-forming step of the first modified example, it is possible to form the SiON film on the wafer 200 in accordance with one or more of process sequences shown below. For example, similar to the embodiments described above, the purge before and/or after the supply of the inert gas (which is plasma-excited) may be omitted.

(Source gas→P→O-containing gas→P→Plasma-excited inert gas→P)×n

(Source gas→P→Plasma-excited inert gas→P→O-containing gas→P)×n

(Source gas→P→Plasma-excited O-containing gas→P→Plasma-excited inert gas→P)×n

(Source gas→P→Plasma-excited inert gas→P→Plasma-excited O-containing gas→P)×n

Even in such a case, it is possible to obtain substantially the same effects as in the embodiments described above or the first modified example described above. That is, even in the case where the cycle of the embodiments described above or the cycle of the first modified example described above further includes the step of supplying the oxygen-containing gas to the wafer 200 and the SiON film is formed on the wafer 200, it is possible to obtain substantially the same effects as in the embodiments described above or the first modified example described above.

### Other Embodiments of Present Disclosure

While the technique of the present disclosure is described in detail by way of the embodiments and the modified examples described above, the technique of the present disclosure is not limited thereto. The technique of the present disclosure may be modified in various ways without departing from the scope thereof.

For example, instead of or in addition to the process sequence in the embodiments described above, that is, instead of or in addition to performing the cycle (which includes the first step, the second step and the third step, and the first step, the second step and the third step are performed in this order in the cycle) a predetermined number of times (n times, where n is an integer of 1 or more), it is possible to change the order of performing each step in the cycle in accordance with one or more of process sequences shown below. Even in such a case, it is possible to obtain substantially the same effects as in the embodiments described above.

(First step→Second step→Third step)×n

(Second step→Third step→First step)×n

(Third step→First step→Second step)×n

However, when a last step in each cycle described above is the first step or the second step, a composition of the uppermost surface of the film (which is finally formed) and the effect of modifying the film may differ from those of the other portions of the film. Therefore, as in process sequences shown below, it is preferable to finely adjust the quality of film on the uppermost surface of the film (which is finally formed) such that, by additionally performing the second step or the third step after a last execution of the cycle is performed, a nitridation degree by the second step or a modification degree by the third step additionally performed are substantially the same as that of layers formed so far.

(Second step→Third Step→First Step)×n→Second Step→Third Step

(Third Step→First Step→Second step)×n→Third Step

For example, instead of or in addition to the process sequence in the embodiments described above, that is, instead of or in addition to performing the cycle (which includes the first step, the second step and the third step, and the first step, the second step and the third step are performed in this order in the cycle) a predetermined number of times (n times, where n is an integer of 1 or more), a cycle (which includes the first step, the second step and the third step, and the third step is performed after a sub-cycle including the first step and the second step is performed a plurality number of times (m times, where m is an integer of 2 or more)) may be performed a predetermined number of times (n times, where n is an integer of 1 or more). Alternatively, a cycle (which includes the first step, the second step and the third step, and a sub-cycle including the second step and the third step is performed a plurality number of times (m times, where m is an integer of 2 or more) after the first step is performed) may be performed a predetermined number of times (n times, where n is an integer of 1 or more). The process sequences in such cases are shown below. Even in such cases, it is possible to obtain substantially the same effects as in the embodiments described above.

(First step→Second step→Third step)×n

(First step→Second step)×m→Third step)×n

(First step→(Second step→Third step)×m)×n

Alternatively, for example, the first step and the second step may be performed while the wafers 200 are supported by the boat 217 as shown in FIG. 7A and the third step may be performed while the wafers 200 are supported by the boat 217 as shown in FIG. 7B or FIG. 7C. That is, the interval (arrangement pitch) P1 of the wafers 200 in the third step may be set to be greater than the interval (arrangement pitch) P2 of the wafers 200 in the first step or the second step (that is, P1>P2). In such a case, for example, it is preferable to set the interval P1 to twice or more than the interval P2 (that is, P1≥2P2), more preferable to set the interval P1 to three times or more than the interval P2 (that is, P1≥3P2), and even more preferable to set the interval P1 to four times or more than the interval P2 (that is, P1≥4P2). For example, in a case where the interval P2 is set to 6 mm to 12 mm, it is preferable to set the interval P1 to 12 mm to 24 mm or more, more preferable to set the interval P1 to 18 mm to 36 mm or more, and even more preferable to set the interval P1 to 24 mm to 48 mm or more. In such a case, the technique of the present disclosure is not limited to an example in which the wafers 200 in the third step are supported by the boat 217 where the interval (arrangement pitch) between adjacent support structures among the support structures 217b is set to 6 mm to 12 mm, for example. That is, the technique of the present disclosure may also be applied to a case where the wafers 200 in the third step are supported by the boat 217 where the interval (arrangement pitch) between adjacent support structures among the support structures 217b itself is set to be within the numerical ranges exemplified above. Further, in such a case, by preparing a first process chamber and a second process chamber (wherein a configuration of the first process chamber and a configuration of the second process chamber are substantially the same as that of the process chamber 201), the first step and the second step may be performed in the first process chamber and the third step may be performed in the second process chamber. Even in such a case, it is possible to obtain substantially the same effects as in the embodiments described above. Further, in such a case, the number of the wafers 200 when the first step and the second step are performed can be set to be greater than the number of the wafers 200 when the third step is performed.

Alternatively, for example, the first step may be performed while the wafers 200 are supported by the boat 217 as shown in FIG. 7A and the second step and the third step may be performed while the wafers 200 are supported by the boat 217 as shown in FIG. 7B or FIG. 7C. That is, the interval (arrangement pitch) P1 of the wafers 200 in the second step or the third step may be set to be greater than the interval (arrangement pitch) P2 of the wafers 200 in the first step (that is, P1>P2). In such a case, for example, it is preferable to set the interval P1 to twice or more than the interval P2 (that is, P1≥2P2), more preferable to set the interval P1 to three times or more than the interval P2 (that is, P1≥3P2), and even more preferable to set the interval P1 to four times or more than the interval P2 (that is, P1≥4P2). For example, in a case where the interval P2 is set to 6 mm to 12 mm, it is preferable to set the interval P1 to 12 mm to 24 mm or more, more preferable to set the interval P1 to 18 mm to 36 mm or more, and even more preferable to set the interval P1 to 24 mm to 48 mm or more. In such a case, the technique of the present disclosure is not limited to an example in which the wafers 200 in the second step or the third step are supported by the boat 217 where the interval (arrangement pitch) between adjacent support structures among the support structures 217b is 6 mm to 12 mm, for example. That is, the technique of the present disclosure may also be applied to a case where the wafers 200 in the second step or the third step are supported by the boat 217 where the interval (arrangement pitch) between adjacent support structures among the support structures 217b itself is set to be within the numerical ranges exemplified above. Further, in such a case, by preparing the first process chamber and the second process chamber (wherein the configuration of the first process chamber and the configuration of the second process chamber are substantially the same as that of the process chamber 201), the first step may be performed in the first process chamber and the second step and the third step may be performed in the second process chamber. Even in such a case, it is possible to obtain substantially the same effects as in the embodiments described above. Further, in such a case, the number of the wafers 200 when the first step is performed can be set to be greater than the number of the wafers 200 when the second step and the third step are performed.

Further, for example, as a method of generating the plasma, in addition to or instead of the capacitively coupled plasma (abbreviated as CCP), an inductively coupled plasma (abbreviated as ICP) may be used. Even in such a case, it is possible to obtain substantially the same effects as in the embodiments described above.

It is preferable that recipes used in processes are prepared individually in accordance with contents of the processes and stored in the memory 121c via an electric communication line or the external memory 123. When starting each process, it is preferable that the CPU 121a selects an appropriate recipe among the recipes stored in the memory 121c in accordance with the contents of each process. Thus, various films of different composition ratios, qualities and thicknesses can be formed in a reproducible manner and in a universal manner by using a single substrate processing apparatus (that is, the substrate processing apparatus described above). In addition, since a burden on an operating personnel of the substrate processing apparatus can be reduced, various processes can be performed quickly while avoiding a malfunction of the substrate processing apparatus.

The recipe described above is not limited to creating a new recipe. For example, the recipe may be prepared by changing an existing recipe stored (or installed) in the substrate processing apparatus in advance. When changing the existing recipe to a new recipe, the new recipe may be installed in the substrate processing apparatus via the electric communication line or a recording medium in which the new recipe is stored. Further, the existing recipe already stored in the substrate processing apparatus may be directly changed to the new recipe by operating the input/output device 122 of the substrate processing apparatus.

For example, the embodiments described above and the modified examples described above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates at a time is used to form the film. For example, the embodiments described above and the modified examples described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process sequences and the process conditions of each process using the substrate processing apparatuses described above may be substantially the same as those of the embodiments described above or the modified examples described above. Even in such a case, it is possible to obtain substantially the same effects as in the embodiments described above or the modified examples described above.

Further, the embodiments described above and modified examples described above may be appropriately combined. The process sequences and the process conditions of each combination thereof may be substantially the same as those of the embodiments described above or the modified examples described above.

### Examples of Embodiments

The SiN film is formed on the wafers by using the substrate processing apparatus of the embodiments described above and by using the process sequence of the embodiments described above. When forming the SiN film, the DCS gas is used as the source gas, the NH3 gas is used as the N- and H-containing gas and the N2 gas is used as the inert gas. Evaluation samples #1 through #4 of four types of the SiN film are manufactured by setting the process pressure in the third step in accordance with the following four pressure conditions (pressure conditions #1 through #4) and by forming the SiN film on the wafers under each of the four pressure conditions. When manufacturing the evaluation samples #1 through #4, the process conditions other than the process pressure in the third step are set to be substantially the same as process conditions within a range of the process conditions in the embodiments described above, and an interval (arrangement pitch) between adjacent wafers among the wafers is set to 15 mm to 40 mm for each of the evaluation samples #1 through #4.
The Pressure condition #1: 0.01 Torr (1.33 Pa)
The Pressure condition #2: 0.02 Torr (2.66 Pa)
The Pressure condition #3: 0.04 Torr (5.32 Pa)
The Pressure condition #4: 0.06 Torr (7.98 Pa)

After manufacturing the evaluation samples #1 through #4, the WER and the thickness of the SiN film on the surface of each wafer corresponding to each of the evaluation samples #1 through #4 are measured. Results of measuring the WER and the thickness of the SiN film are shown in FIGS. 8 through 11. In FIGS. 8 through 11, a horizontal axis indicates a distance (radius) from the center of the wafer 200, where “0 mm” indicates the central portion of the wafer 200, “150 mm” and “−150 mm” indicates the outer periphery (edge) of the wafer 200. In FIGS. 8 through 11, a vertical axis on a left portion indicates the WER in an arbitrary unit (a.u.), and a vertical axis on a right portion indicates the thickness of the SiN film in an arbitrary unit (a.u.). In the figures, a symbol “0” indicates the thickness of the SiN film, and a symbol “e” indicates the WER of the SiN film. In FIGS. 8 through 11, measurement results of the WER of the SiN film and the thickness of the SiN film for the evaluation samples #1 through #4 are illustrated, respectively.

Referring to FIG. 8, it is confirmed that, in the SiN film of the evaluation sample #1 in which the process pressure in the third step is set to the pressure condition #1, the WER at the outer periphery of the wafer 200 is higher than the WER at the central portion of the wafer 200. In addition, it is also confirmed that, in the SiN film of the evaluation sample #1, the thickness of the SiN film at the outer periphery of the wafer 200 is thicker than the thickness of the SiN film at the central portion of the wafer 200. That is, it is confirmed that, in the SiN film of the evaluation sample #1, both of the WER uniformity on the surface of the wafer 200 and the thickness uniformity of the SiN film on the surface of the wafer 200 are not appropriate. Further, it is considered that, since the density of the SiN film is lowered due to the ion attack by the N2+ generated when the N2 gas is plasma-excited under the pressure condition #1, the WER of the SiN film of the evaluation sample #1 increases at the outer periphery of the wafer 200. Further, it is considered that, since the ion attack by the N2+ generated when the N2 gas is plasma-excited under the pressure condition #1 may destroy the structure of the SiN film at the outer periphery of the wafer 200 and the portion of the SiN film destructed as described above may change to the sparse film, the thickness of the SiN film of the evaluation sample #1 becomes thicker at the outer periphery of the wafer 200.

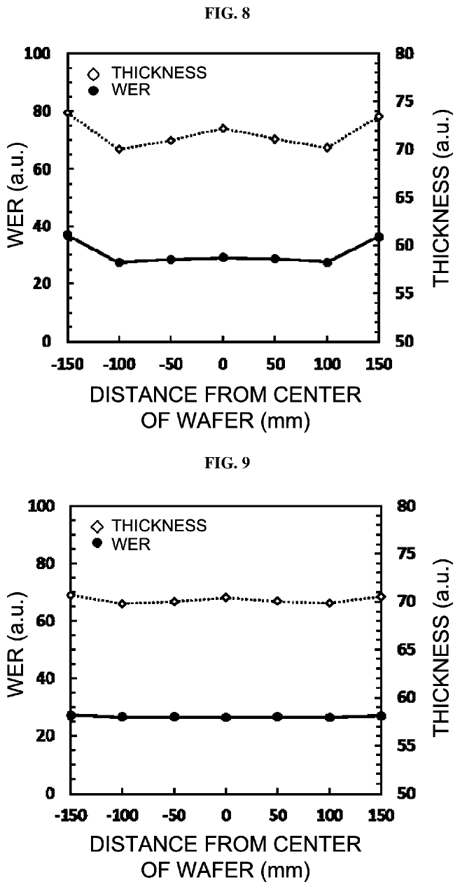

Referring to FIG. 9, it is confirmed that, in the SiN film of the evaluation sample #2 in which the process pressure in the third step is set to the pressure condition #2, the WER is substantially the same at the outer periphery of the wafer 200 and the central portion of the wafer 200. In addition, it is also confirmed that, in the SiN film of the evaluation sample #2, the thickness of the SiN film is substantially the same at the outer periphery of the wafer 200 and the central portion of the wafer 200. That is, it is confirmed that, in the SiN film of the evaluation sample #2, both of the WER uniformity on the surface of the wafer 200 and the thickness uniformity of the SiN film on the surface of the wafer 200 are excellent.

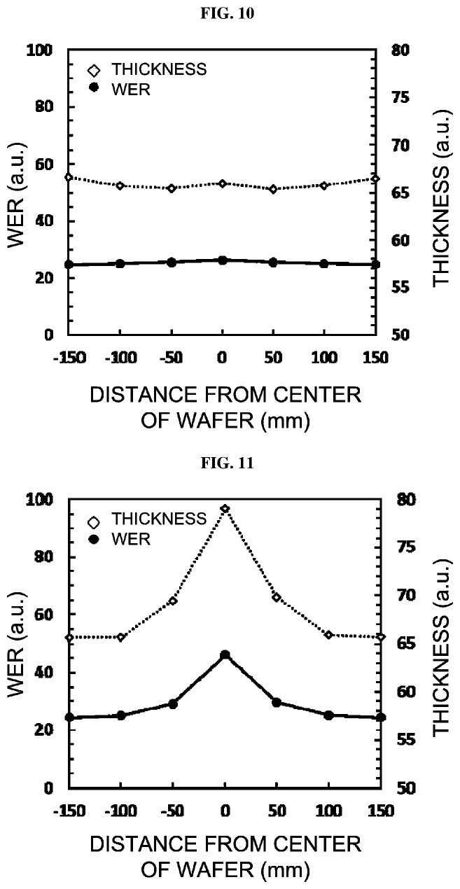

Referring to FIG. 10, it is confirmed that, in the SiN film of the evaluation sample #3 in which the process pressure in the third step is set to the pressure condition #3, the WER is substantially the same at the outer periphery of the wafer 200 and the central portion of the wafer 200. In addition, it is also confirmed that, in the SiN film of the evaluation sample #3, the thickness of the SiN film is substantially the same at the outer periphery of the wafer 200 and the central portion of the wafer 200. That is, it is confirmed that, in the SiN film of the evaluation sample #3, both of the WER uniformity on the surface of the wafer 200 and the thickness uniformity of the SiN film on the surface of the wafer 200 are excellent.

Referring to FIG. 11, it is confirmed that, in the SiN film of the evaluation sample #4 in which the process pressure in the third step is set to the pressure condition #4, the WER at the central portion of the wafer 200 is higher than the WER at the outer periphery of the wafer 200. In addition, it is also confirmed that, in the SiN film of the evaluation sample #4, the thickness of the SiN film at the central portion of the wafer 200 is thicker than the thickness of the SiN film at the outer periphery of the wafer 200. That is, it is confirmed that, in the SiN film of the evaluation sample #4, both of the WER uniformity on the surface of the wafer 200 and the thickness uniformity of the SiN film on the surface of the wafer 200 are not appropriate. Further, it is considered that, since the active species such as the N* and the N2* (in particular, the N*) generated when the N2 gas is plasma-excited under the pressure condition #4 are more likely to be deactivated before reaching the center portion of the wafer 200 and thereby an effect of modifying the SiN film at the central portion of the wafer 200 is insufficient, the WER of the SiN film of the evaluation sample #4 increases at the central portion of the wafer 200. Further, it is considered that, since the active species such as the N* and the N2* (in particular, the N*) generated when the N2 gas is plasma-excited under the pressure condition #4 are more likely to be deactivated before reaching the center portion of the wafer 200 and thereby an effect of densifying the SiN film at the central portion of the wafer 200 is insufficient, the thickness of the SiN film of the evaluation sample #4 becomes thicker at the central portion of the wafer 200.

From the above, it is confirmed that, by setting the process pressure in the third step to 0.02 Torr (2.66 Pa) to 0.04 Torr (5.32 Pa), it is possible to form the high quality SiN film (that is, the SiN film whose WER uniformity on the surface of the wafer 200 and whose thickness uniformity on the surface of the wafer 200 are remarkably high). Further, it is confirmed that, by setting the process pressure in the third step to 2 Pa to 6 Pa, it is possible to form the high quality SiN film (that is, the SiN film whose WER uniformity on the surface of the wafer 200 and whose thickness uniformity on the surface of the wafer 200 are remarkably high).

According to some embodiments of the present disclosure, it is possible to provide the technique capable of forming the high quality film at the low temperature using the plasma.

What is claimed is:

1. A substrate processing method comprising:
(A) forming a film on a substrate by performing a cycle a predetermined number of times, wherein the cycle comprises:
(a) supplying a source gas to the substrate;
(b) supplying a plasma-excited gas containing nitrogen and hydrogen to the substrate by exciting a gas containing nitrogen and hydrogen into a plasma state; and
(c) supplying a plasma-excited inert gas to the substrate by exciting an inert gas into a plasma state,
wherein a pressure of a space where the substrate is present is set to be lower in (c) than in (b).

2. The substrate processing method of claim 1, wherein the pressure of the space where the substrate is present in (c) is set to be 2 Pa or more and 6 Pa or less.

3. The substrate processing method of claim 1, wherein the pressure of the space where the substrate is present in (c) is set to be 2.66 Pa or more and 5.32 Pa or less.

4. The substrate processing method of claim 1, wherein the pressure of the space where the substrate is present in (c) is set to be 3 Pa or more and 4 Pa or less.

5. The substrate processing method of claim 1, wherein a time duration of supplying the plasma-excited inert gas in (c) is set to be longer than a time duration of supplying the plasma-excited gas containing nitrogen and hydrogen in (b).

6. The substrate processing method of claim 1, wherein a time duration of supplying the plasma-excited inert gas in (c) is set to be longer than a time duration of supplying the source gas in (a).

7. The substrate processing method of claim 1, wherein the inert gas comprises at least one of nitrogen gas or a rare gas.

8. The substrate processing method of claim 1, wherein the inert gas comprises N2 gas.

9. The substrate processing method of claim 1, wherein the inert gas comprises Ar gas.

10. The substrate processing method of claim 1, wherein the gas containing nitrogen and hydrogen comprises at least one among NH3 gas, N2H2 gas, N2H4 gas or N3H8 gas.

11. The substrate processing method of claim 1, wherein the source gas comprises a halosilane-based gas.

12. The substrate processing method of claim 1, wherein, in (c), the inert gas is excited into the plasma state in a process vessel in which the substrate is processed by applying an electric power to an electrode provided outside the process vessel.

13. The substrate processing method of claim 1, wherein (A) is performed while a plurality of substrates comprising the substrate are supported by a substrate support in a process vessel in a state where an interval between adjacent substrates among the plurality of substrates is set to be greater than a reference interval that enables the substrate support to accommodate a maximum number of substrates supportable by the substrate support.

14. The substrate processing method of claim 13, wherein, in (A), the interval between adjacent substrates among the plurality of substrates is set to be twice or more the reference interval.

15. The substrate processing method of claim 1, wherein (A) is performed while a plurality of substrates comprising the substrate are arranged in a process vessel in a state where an interval between adjacent substrates among the plurality of substrates is set to 12 mm or more and 60 mm or less.

16. The substrate processing method of claim 1, wherein (A) is performed while a plurality of substrates comprising the substrate are arranged in a process vessel in a state where an interval between adjacent substrates among the plurality of substrates is set to 15 mm or more and 60 mm or less.

17. The substrate processing method of claim 1, wherein, in (c), the plasma-excited inert gas is supplied to the substrate through an edge of the substrate.

18. A method of manufacturing a semiconductor device comprising the substrate processing method of claim 1.

19. A substrate processing apparatus comprising:
a process vessel in which a substrate is processed;
a source gas supplier through which a source gas is supplied into the process vessel;
a gas supplier of a gas containing nitrogen and hydrogen through which the gas containing nitrogen and hydrogen is supplied into the process vessel;
an inert gas supplier through which an inert gas is supplied into the process vessel;
a plasma exciter configured to excite a gas into a plasma state;
a pressure regulator configured to adjust an inner pressure of the process vessel; and
a controller configured to be capable of controlling the source gas supplier, the gas supplier of the gas containing nitrogen and hydrogen, the inert gas supplier, the plasma exciter and the pressure regulator so as to perform:
forming a film on the substrate by performing a cycle a predetermined number of times, wherein the cycle comprises:
(a) supplying the source gas to the substrate in the process vessel;
(b) supplying a plasma-excited gas containing nitrogen and hydrogen to the substrate in the process vessel by exciting the gas containing nitrogen and hydrogen into the plasma state; and
(c) supplying a plasma-excited inert gas to the substrate in the process vessel by exciting the inert gas into the plasma state,
wherein the inner pressure of the process vessel is set to be lower in (c) than in (b).

20. A non-transitory computer-readable recording medium storing a program that causes, by a computer, a substrate processing apparatus to perform:
forming a film on a substrate by performing a cycle a predetermined number of times, wherein the cycle comprises:
(a) supplying a source gas to the substrate;
(b) supplying a plasma-excited gas containing nitrogen and hydrogen to the substrate by exciting a gas containing nitrogen and hydrogen into a plasma state; and
(c) supplying a plasma-excited inert gas to the substrate by exciting an inert gas into a plasma state,
wherein a pressure of a space where the substrate is present is set to be lower in (c) than in (b).
